(19) United States
(12) Patent Application Publication
(10) Pub. No.: US 2018/0024746 A1
(43) Pub. Date: Jan. 25, 2018

(54) METHODS OF ENCODING AND STORING MULTIPLE VERSIONS OF DATA, METHOD OF DECODING ENCODED MULTIPLE VERSIONS OF DATA AND DISTRIBUTED STORAGE SYSTEM

(71) Applicant: Nanyang Technological University, Singapore (SG)

(72) Inventors: Harshan Jagadeesh, Singapore (SG); Anwitaman Datta, Singapore (SG); Frederique Oggier, Singapore (SG)

(21) Appl. No.: 15/550,317

(22) PCT Filed: Feb. 12, 2016
(86) PCT No.: PCT/SG2016/050074

§ 371 Date: Aug. 10, 2017

(30) Foreign Application Priority Data
Feb. 13, 2015 (SG) 10201501135Y

(51) Int. Cl. G06F 3/06; H03M 13/15

(52) U.S. Cl. CPC G06F 3/064; G06F 3/0608; G06F 3/067; H03M 13/154

(57) ABSTRACT

There is provided a method of encoding multiple versions of data. The method includes computing a difference between a version of a data object and a subsequent version of the data object to produce a difference object, determining a sparsity level of the difference 10 object; determining whether the sparsity level satisfies a predetermined condition; and compressing the difference object to produce a compressed difference object and erasure encoding the compressed difference object to produce a codeword if the sparsity level is determined to satisfy the predetermined condition. There is also provided a corresponding method of decoding encoded multiple versions of data, a method of storing multiple 15 versions of data in a distributed storage system, and a distributed storage system.

### CROSS-REFERENCE TO RELATED APPLICATION

This application claims the benefit of priority of Singapore Patent Application No. 10201501135Y, filed 13 Feb. 2015, the content of which being hereby incorporated by reference in its entirety for all purposes.

### TECHNICAL FIELD

The present invention generally relates to a method of encoding multiple versions of data, a method of decoding encoded multiple versions of data, a distributed storage system, and a method of storing multiple versions of data in the distributed storage system.

### BACKGROUND

Distributed storage systems enable the storage of huge amount of data across networks of storage nodes. Redundancy of the stored data is critical to ensure fault tolerance. While data replication remains a practical way of realizing this redundancy, the past years have witnessed the adoption of erasure codes for data archival (e.g. in Microsoft Azure, Hadoop FS, or Google File System (GFS)), which offer a better trade-off between storage overhead and fault tolerance. Design of erasure coding techniques amenable to efficient repairs has accordingly garnered a huge attention.

Conventional techniques of storing multiple versions of data are loosely related to the issues of efficient updates, and of deduplication. Existing works on update of erasure coded data focus on the computational and communication efficiency in carrying out the updates, with the goal to store only the latest version of the data, and thus do not delve into efficient storage or manipulation of the previous versions. Deduplication is the process of eliminating duplicate data blocks, which is used in order to eliminate unnecessary redundancy.

The need to store multiple versions of data arises in many scenarios. For instance, when editing and updating files, users may want to explicitly create a version repository using a framework like Subversion (SVN) or Git. Cloud based document editing or storage services also often provide the users access to older versions of the documents. Another scenario is that of system level back-up, where directories, whole file systems or databases are archived, and versions refer to the different system snapshots. In either of the two file centric settings, irrespective of whether a working copy used during editing is stored locally or on the cloud, or in a system level back up, say using copy-on-write, the back-end storage system needs to preserve the different versions reliably, and can leverage on erasure coding for reducing the storage overheads.

A naive approach may be to apply coding to each version independently. However, such a naive approach may be impractical due to inefficiencies in coding and storage.

A need therefore exists to provide a method of encoding multiple versions of data for efficient storage of the multiple versions of data, and more particularly, a method for coding and storing multiple versions of data in a storage efficient manner in a distributed storage system. It is against this background that the present invention has been developed.

### SUMMARY

According to a first aspect of the present invention, there is provided a method of encoding multiple versions of data, the method comprising:
computing a difference between a version of a data object and a subsequent version of the data object to produce a difference object;
determining a sparsity level of the difference object;
determining whether the sparsity level satisfies a predetermined condition; and
compressing the difference object to produce a compressed difference object and erasure encoding the compressed difference object to produce a codeword if the sparsity level is determined to satisfy the predetermined condition.

In various embodiments, compressing the difference object comprises applying compressed sensing to the difference object to produce the compressed difference object.

In various embodiments, applying compressed sensing to the difference object comprises applying a measurement matrix to the difference object to produce the compressed difference object, wherein the measurement matrix satisfies a condition that every of a number of columns of the measurement matrix are linearly independent, the number being two times the sparsity level of the difference object.

In various embodiments, the difference object comprises a matrix representing the difference between said version of the data object and said subsequent version of the data object.

In various embodiments, the predetermined condition relates to a sparsity level threshold.

In various embodiments, erasure encoding the compressed difference object comprises applying an erasure code to the compressed difference object, the erasure code being selected from a set of erasure codes based on the sparsity level of the difference object determined, the set of erasure codes comprising a plurality of erasure codes for a plurality of sparsity levels, respectively.

In various embodiments, the data object is divided into a plurality of data blocks and the predetermined condition is whether the sparsity level of the difference object is less than half of the number of the plurality of data chunks.

In various embodiments, one erasure code is provided for all sparsity levels that satisfy the predetermined condition, and erasure encoding the compressed difference object comprises applying said one erasure code to the compressed difference object.

In various embodiments, the predetermined condition is whether the sparsity level of the difference object is less than or equal to a predetermined threshold level.

In various embodiments, compressing the difference object comprises applying a Cauchy Matrix to the difference object to produce the compressed difference object.

In various embodiments, a plurality of erasure codes is provided for a plurality of sparsity levels, and erasure encoding the compressed difference object comprises applying one of the plurality of erasure codes to the compressed difference object.

In various embodiments, the method further comprises erasure encoding the difference object to produce a codeword if the sparsity level of the difference object is determined to not satisfy the predetermined condition.

In various embodiments, the method further comprises erasure encoding said subsequent version of the data object to produce a codeword if the sparsity level of the difference object is determined to not satisfy the predetermined condition.

In various embodiments, the codeword produced is for said subsequent version of the data object.

In various embodiments, the codeword produced is for said version of the data object.

In various embodiments, the method further comprises erasure encoding said subsequent version of the data object to produce a codeword for said subsequent version of the data object.

In various embodiments, the method further comprises distributing components of the codeword produced to a plurality of storage nodes for storage.

In various embodiments, the method further comprises zero padding the data object with a plurality of zero pads such that the data object comprises file contents and the plurality of zero pads.

In various embodiments, the number of zero pads in said subsequent version of the data object increases or decreases with respect to the number of zero pads in said version of the data object based on a change in the size of the file contents in said subsequent version of the data object with respect to the size of the file contents in said version of the data object.

In various embodiments, the number of zero pads in said subsequent version of the data object decreases with respect to the number of zero pads in said version of the data object when the change results in an increase in the size of the file contents in the subsequent version of the data object with respect to the size of the file contents in said version of the data object, and

the number of zero pads in said subsequent version of the data object increases with respect to the number of zero pads in said version of the data object when the change results in a decrease in the size of the file contents in said subsequent version of the data object with respect to the size of the file contents in said version of the data object.

According to a second aspect of the present invention, there is provided a method of decoding encoded multiple versions of data, the encoded multiple versions of data comprising a plurality of codewords, each codeword corresponding a respective version of a data object, the method comprising:

erasure decoding a codeword corresponding to a version of the data object from the plurality of codewords to obtain a compressed difference object, the difference object representing a difference between said version of the data object and another version of the data object;

decompressing the compressed difference object to recover the difference object; and

recovering said version of the data object based on at least the recovered difference object and said another version of the data object.

According to a third aspect of the present invention, there is provided an encoder system for encoding multiple versions of data, the encoder comprising:

a difference object generator module configured to compute a difference between a version of a data object and a subsequent version of the data object to produce a difference object;

a sparsity level determination module configured to determine a sparsity level of the difference object;

a sparsity level comparator module configured to determine whether the sparsity level satisfies a predetermined condition;

a compression module configured to compress the difference object to produce a compressed difference object; and

an erasure encoder configured to encode the compressed difference object to produce a codeword,

wherein the compression module is configured to compress the difference object and the erasure encoder is configured to encode the compressed difference object if the sparsity level is determined by the sparsity level comparator module to satisfy the predetermined condition.

In various embodiments, the predetermined condition relates to a sparsity level threshold.

According to a fourth aspect of the present invention, there is provided a distributed storage system, the system comprising:

a plurality of secondary servers, each secondary server configured to store codewords for multiple versions of a data object; and

a group server associated with the plurality of secondary servers, wherein

each secondary server comprises a difference object generator module configured to compute a difference between a version of the data object and a subsequent version of the data object to produce a difference object, and

the group server comprises:
a sparsity level determination module configured to determine a sparsity level of the difference object received from the secondary server;
a sparsity level comparator module configured to determine whether the sparsity level satisfies a predetermined condition;
a compression module configured to compress the difference object to produce a compressed difference object; and
an erasure encoder configured to encode the compressed difference object to produce a codeword for storing in the secondary server,
wherein the compression module is configured to compress the difference object and the erasure encoder is configured to encode the compressed difference object if the sparsity level is determined by the sparsity level comparator module to satisfy the predetermined condition.

In various embodiments, the distributed storage system further comprises a master server configured for facilitating communication between a client and a plurality of the group servers for storing multiple versions of data in the plurality of secondary servers.

In various embodiments, the predetermined condition relates to a sparsity level threshold.

According to a fifth aspect of the present invention, there is provided a method of storing multiple versions of data in a distributed storage system, the distributed storage system comprising:

a plurality of secondary servers, each secondary server configured to store codewords for multiple versions of a data object; and

a group server associated with the plurality of secondary servers,

the method comprising:
computing, at one of the plurality of secondary servers, a difference between a version of a data object and a subsequent version of the data object to produce a difference object;
determining, at the group server, a sparsity level of the difference object received from the secondary server;
determining, at the group server, whether the sparsity level satisfies a predetermined condition; and
compressing, at the group server, the difference object to produce a compressed difference object and erasure encoding, at the group server, the compressed difference object to produce a codeword for storage in the secondary server if the sparsity level is determined to satisfy the predetermined condition.

In various embodiments, the predetermined condition relates to a sparsity level threshold.

According to a sixth aspect of the present invention, there is provided a computer program product, embodied in one or more computer-readable storage mediums, comprising instructions executable by one or more computer processors to perform a method of encoding multiple versions of data, the method comprising:

computing a difference between a version of a data object and a subsequent version of the data object to produce a difference object;

determining a sparsity level of the difference object;

determining whether the sparsity level satisfies a predetermined condition; and

compressing the difference object to produce a compressed difference object and erasure encoding the compressed difference object to produce a codeword if the sparsity level is determined to satisfy the predetermined condition.

### BRIEF DESCRIPTION OF THE DRAWINGS

Embodiments of the present invention will be better understood and readily apparent to one of ordinary skill in the art from the following written description, by way of example only, and in conjunction with the drawings, in which:

FIG. 1 depicts a flow diagram illustrating a method of encoding multiple versions of data according to various embodiments of the present invention;

FIG. 2 depicts a flow diagram illustrating a method of decoding encoded multiple versions of data (e.g., encoded by the method as described with reference to FIG. 1) according to various embodiments of the present invention;

FIG. 3 depicts a schematic block diagram of an encoder system for encoding multiple versions of data according to various embodiments of the present invention;

FIG. 4 depicts a schematic block diagram of a distributed storage system according to various embodiments of the present invention;

FIG. 5 depicts a flow diagram of a method of storing multiple versions of data in a distributed storage system (e.g., the distributed storage system as described with reference to FIG. 4) according to various embodiments of the present invention;

FIG. 6 depicts a schematic drawing of an exemplary computer system;

FIG. 7 depicts a schematic diagram illustrating an overview of a method of encoding multiple versions of data according to various example embodiments of the present invention;

FIG. 8 depicts a differential erasure coding procedure according to various example embodiments of the present invention;

FIG. 9 depicts plots comparing the probability that both versions (a version of a data object and a subsequent version of the data object) against the probability of a node failure for both distributed and collocated strategies according to various example embodiments of the present invention;

FIG. 10 depicts a reverse DEC procedure according to various example embodiments of the present invention;

FIG. 11 depicts a two-level forward DEC procedure according to various example embodiments of the present invention;

FIGS. 12A to 12D depict plots of the Probability Mass Functions (PMFs) in Equations 14 to 17 described herein respectively for various parameters according to various example embodiments of the present invention;

FIGS. 13A to 13D depict plots of the average percentage reduction in the I/O reads and storage size for the PMFs as described with reference to FIGS. 12A to 12D, respectively, when L=2 according to various example embodiments of the present invention;

FIGS. 14A to 14D depict plots of the average percentage increase in the I/O reads to retrieve the latest version of data object (the 2^{nd} version in the example) for the PMFs as described with reference to FIGS. 12A to 12D, respectively, when L=2 according to various example embodiments of the present invention;

FIG. 15 depicts plots of the average number of I/O reads against the average storage size for the PMFs as described with reference to FIGS. 12A to 12D, respectively, according to various example embodiments of the present invention;

FIGS. 16A to 16D depict plots the average percentage reduction in the total storage size and total I/O reads number for the PMFs as described with reference to FIGS. 12A to 12D, respectively, when L=10, according to various example embodiments of the present invention;

FIGS. 17A and 17B depict plots of the I/O read numbers and the storage size for Examples 3 and 4 described herein, respectively, for when L=20, according to various example embodiments of the present invention. FIG. 17A shows the number of I/O reads to retrieve only the l-th version for 1≦l≦20, and FIG. 17B provide the shows the total storage size till the l-th version for 1≦l≦20;

FIG. 18 depicts plots illustrating the storage size required by three schemes/techniques, (i) sparsity exploiting coding (SEC), (ii) selective encoding, and (iii) the non-differential technique, for different versions of the data object discussed in Examples 7 to 12 herein according to various example embodiments of the present invention;

FIGS. 19A to 19D depict plots illustrating the three techniques with respect to insertions, and more specifically, the average storage size for the second version of the data object against workloads comprising random insertions according to various example embodiments of the present invention;

FIGS. 20A to 20D depict plots illustrating the three techniques with respect to deletions, and more specifically, the average storage size for the second version of the data object against workloads comprising random deletions according to various example embodiments of the present invention;

FIGS. 21A and 21B depict plots comparing allocation strategies for the three techniques against random insertions according to various example embodiments of the present invention;

FIGS. 22A and 22B depict plots comparing different choices of (Δ, δ) for V=10000 and k=8, and illustrate the average storage size for the second version of the data object against workloads comprising random insertions according to various example embodiments of the present invention;

FIG. 23 depicts plots comparing SEC methods with and without bit striping according to various example embodiments of the present invention;

FIG. 24A depicts plots comparing SEC methods with and without bit striping against bursty insertions with parameters Dε{5, 10, 30, 60} according to various example embodiments of the present invention;

FIG. 24B depicts plots comparing SEC methods with and without bit striping against randomly distributed single insertions with parameters Pε{5, 10, 30, 60} according to various example embodiments of the present invention;

FIG. 25 depicts a snapshot of the metadata when the first version of the data object in Example 7 is saved into DiVers according to an example embodiment of the present invention;

FIG. 26 depicts a snapshot of the metadata for the first version capturing the changes in its contents when the second version of the data object is saved into DiVers according to the example embodiment of the present invention;

FIG. 27 depicts a snapshot of the metadata for the second version discussed in Example 9 herein according to the example embodiments of the present invention; and

FIG. 28 depicts a schematic diagram of a distributed storage system (DiVers architecture) according to various example embodiments of the present invention.

### DETAILED DESCRIPTION

Embodiments of the present invention provide methods of encoding multiple versions of data for efficient storage of the multiple versions of data. Various embodiments of the present invention provide methods for coding and storing multiple versions of data in a storage efficient manner in a distributed storage system, in particular, in an erasure coded distributed storage system.

While most conventional applications of erasure codes to storage have so far focus on archival, and cold data (essentially data that does not mutate), embodiments of the present invention advantageously provide erasure coding algorithms/methods based on sparse sampling techniques, which have been found to lead to a significant reduction of storage overheads (simulations with artificial workloads have shown 20-70% savings, which will be discussed later) when storing multiple versions of mutable content. In particular, the erasure coding algorithms have been designed to reduce the storage overhead when storing multiple versions of mutable data, by exploiting the redundancy across versions. The erasure coding methods according to various embodiments have been found through experimental studies to display a number of advantages with respect to e.g., a naive approach of encoding all versions with erasure codes, for example: (i) gain in storage overhead (the erasure coding methods according to various embodiments have been found to save storage space with respect to the naive approach or other ways to store multiple versions of data using state-of-the-art erasure coded storage systems), and (ii) gain in I/O (Input/Output) reads (the erasure coding methods according to various embodiments have been found to reduce the amount of I/O operations when reading multiple versions of the data, thus yielding good runtime performance). Although various embodiments of the present invention may provide erasure coding methods which focus on providing benefit in terms of storage overhead, further embodiments of the present invention also provide coding strategies to improve I/O operations.

Accordingly, various embodiments of the present invention provide a differential erasure coding (DEC) method/technique (which may also be referred to as a sparsity exploiting coding (SEC) method/technique) that explicitly takes into account the redundancies across versions, and exploits the sparsity of information in the differences amongst versions. In particular, according to various embodiments of the present invention, the DEC exploits the sparsity in the difference across consecutive versions in order to store it in a compressed manner, thus leading to savings in storage. In various embodiments, techniques from compressed sensing are applied to reduce the storage overhead (experiments conducted with synthetic workloads, which will be discussed later, have shown storage savings between 20-70% while storing even only tens of versions) suitable for back-end storage systems catering to versioned data. When all the versions are fetched in ensemble, there is also an equivalent gain in I/O operations. This comes at an increased I/O overhead when accessing individual versions. Embodiments of the present invention accordingly provide techniques to optimize the above DEC, and demonstrate that they ameliorate the drawbacks adequately without compromising the gains, thus advantageously improving the usability/practicability of the DEC disclosed herein according to various embodiments of the present invention.

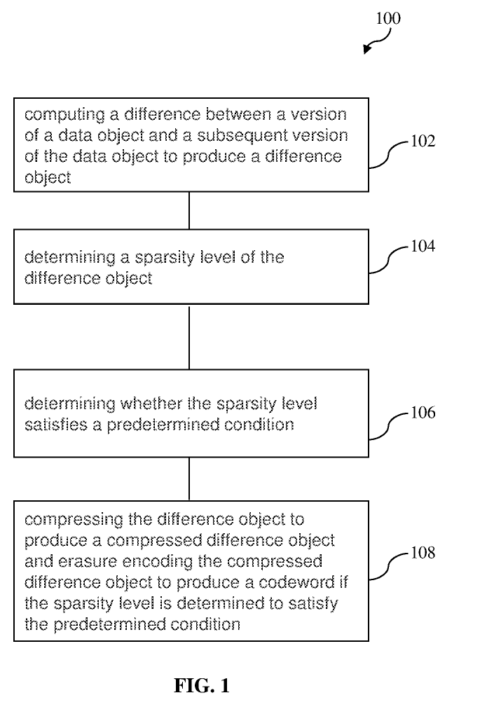

FIG. 1 depicts a flow diagram illustrating a method 100 of encoding multiple versions of data according to various embodiments of the present invention. The method 100 comprises a step 102 of computing a difference between a version of a data object and a subsequent version of the data object to produce a difference object, a step 104 of determining a sparsity level of the difference object, a step 106 of determining whether the sparsity level satisfies a predetermined condition, and a step 108 of compressing the difference object to produce a compressed difference object and erasure encoding the compressed difference object to produce a codeword if the sparsity level is determined to satisfy the predetermined condition. Accordingly, the method 100 advantageously takes into account the redundancies across versions of data and furthermore, examines the sparsity of information in the difference amongst versions so as to compress the difference object when a predetermined condition is satisfied to advantageously reduce the storage overhead for storing multiple versions of data.

In various embodiments, compressing the difference object comprises applying compressed sensing to the difference object to produce the compressed difference object. In various embodiments, applying compressed sensing to the difference object may comprise applying a measurement matrix to the difference object to produce the compressed difference object, whereby the measurement matrix satisfies a condition that every of a number of columns of the measurement matrix are linearly independent, the number being two times the sparsity level of the difference object.

In various embodiments, the difference object comprises a matrix representing the difference between the above-mentioned version of the data object and the above-mentioned subsequent version of the data object.

In various embodiments, the predetermined condition relates to a sparsity level threshold.

In various embodiments, erasure encoding the compressed difference object comprises applying an erasure code to the compressed difference object, the erasure code being selected from a set of erasure codes based on the sparsity level of the difference object determined, the set of erasure codes comprising a plurality of erasure codes for a plurality of sparsity levels, respectively.

In various embodiments, the data object is divided into a plurality of data blocks and the predetermined condition is whether the sparsity level of the difference object is less than half of the number of the plurality of data chunks.

In various embodiments, one erasure code is provided for all sparsity levels that satisfy the predetermined condition, and erasure encoding the compressed difference object comprises applying said one erasure code to the compressed difference object.

In various embodiments, the predetermined condition is whether the sparsity level of the difference object is less than or equal to a predetermined threshold level.

In various embodiments, compressing the difference object comprises applying a Cauchy Matrix to the difference object to produce the compressed difference object.

In various embodiments, a plurality of erasure codes is provided for a plurality of sparsity levels, and erasure encoding the compressed difference object comprises applying one of the plurality of erasure codes to the compressed difference object.

In various embodiments, the method 100 further comprises erasure encoding the difference object to produce a codeword if the sparsity level of the difference object is determined to not satisfy the predetermined condition.

In various embodiments, the method 100 further comprises erasure encoding said subsequent version of the data object to produce a codeword if the sparsity level of the difference object is determined to not satisfy the predetermined condition.

In various embodiments, the codeword produced is for the above-mentioned subsequent version of the data object. For example, in the case of forward differential erasure coding (which will be described later) in various example embodiments of the present invention.

In various embodiments, the codeword produced is for the above-mentioned version of the data object. For example, in the case of reverse differential erasure coding (which will be described later) in various example embodiments of the present invention.

In various embodiments, the method 100 further comprises erasure encoding the above-mentioned subsequent version of the data object to produce a codeword for the above-mentioned subsequent version of the data object. For example, in the case of an optimized erasure encoding as will be described later in an exemplary embodiment of the present invention.

In various embodiments, the method 100 further comprises distributing components of the codeword produced to a plurality of storage nodes for storage such as in a distributed storage system.

In various embodiments, the method 100 further comprises zero padding the data object with a plurality of zero pads such that the data object comprises file contents and the plurality of zero pads. For example, this advantageously promotes sparsity between versions of data object and enables the method 100 to handle changes in the size/length of the file contents in the data object between versions of the data object.

In various embodiments, the number of zero pads in the above-mentioned subsequent version of the data object increases or decreases with respect to the number of zero pads in the above-mentioned version of the data object based on a change in the size of the file contents in the above-mentioned subsequent version of the data object with respect to the size of the file contents in the above-mentioned version of the data object.

In various embodiments, the number of zero pads in the above-mentioned subsequent version of the data object decreases with respect to the number of zero pads in the above-mentioned version of the data object when the change results in an increase in the size of the file contents in the above-mentioned subsequent version of the data object with respect to the size of the file contents in the above-mentioned version of the data object, and the number of zero pads in the above-mentioned subsequent version of the data object increases with respect to the number of zero pads in the above-mentioned version of the data object when the change results in a decrease in the size of the file contents in the above-mentioned subsequent version of the data object with respect to the size of the file contents in the above-mentioned version of the data object.

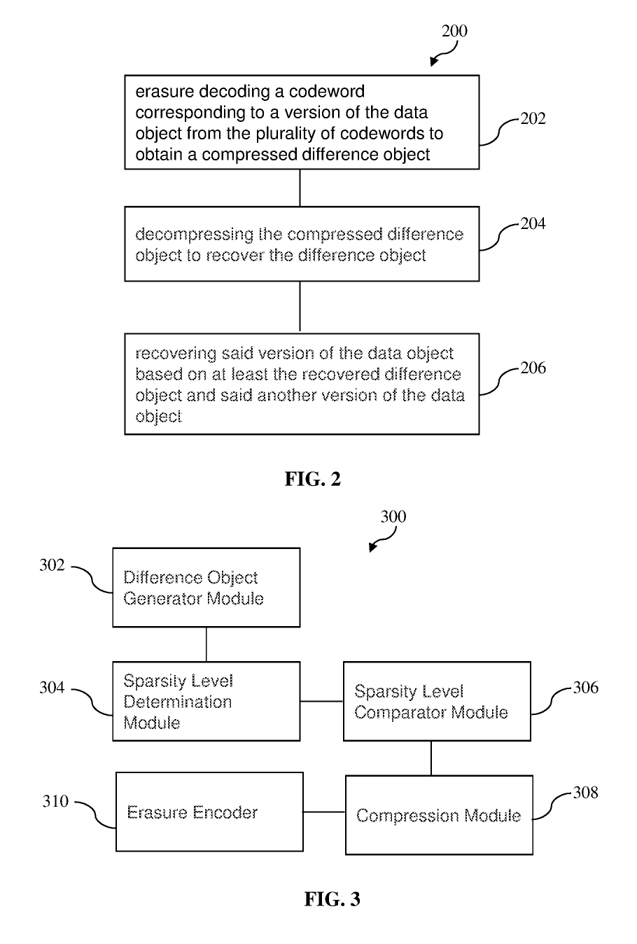

FIG. 2 depicts a flow diagram illustrating a method 200 of decoding encoded multiple versions of data (e.g., encoded by the above-described method 100) according to various embodiments of the present invention, the encoded multiple versions of data comprising a plurality of codewords, each codeword corresponding a respective version of a data object. The method 200 comprising a step 202 of erasure decoding a codeword corresponding to a version of the data object from the plurality of codewords to obtain a compressed difference object, the difference object representing a difference between the above-mentioned version of the data object and another version of the data object, a step 204 of decompressing the compressed difference object to recover the difference object, and a step 206 of recovering the above-mentioned version of the data object based on at least the recovered difference object and the above-mentioned another version of the data object.

FIG. 3 depicts a schematic block diagram of an encoder system 300 for encoding multiple versions of data according to various embodiments of the present invention. In various embodiments, the encoder system 300 is operable to perform the above-described method 100 of encoding multiple versions of data. The encoder system 300 comprises a difference object generator module 302 configured to compute a difference between a version of a data object and a subsequent version of the data object to produce a difference object, a sparsity level determination module 304 configured to determine a sparsity level of the difference object, a sparsity level comparator module 306 configured to determine whether the sparsity level satisfies a predetermined condition, a compression module 308 configured to compress the difference object to produce a compressed difference object, and an erasure encoder 310 configured to encode the compressed difference object to produce a codeword. In particular, the compression module 308 is configured to compress the difference object and the erasure encoder 310 is configured to encode the compressed difference object if the sparsity level is determined by the sparsity level comparator module 306 to satisfy the predetermined condition.

It will be appreciated that the above-mentioned modules of the encoder system 300 may be implemented or located/stored in one device or in separate devices for various purposes. As an example only and without limitation, the difference object generator module 302 may be implemented or located/stored in a secondary server (e.g., chunk server) and the sparsity level determination module 304, the sparsity level comparator module 306, the compression module 308, and the erasure encoder 310 may be implemented or located/stored in a group server serving a group of secondary servers.

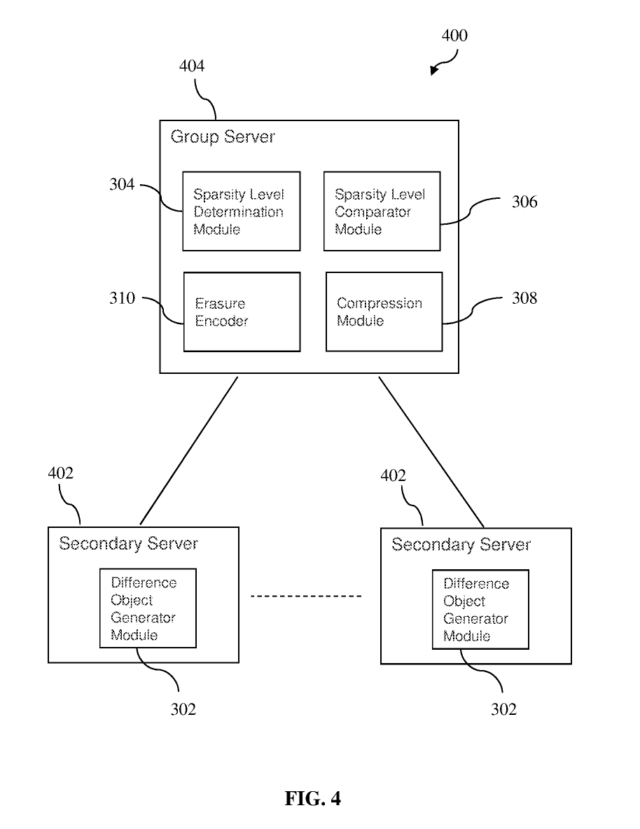

FIG. 4 depicts a schematic block diagram of a distributed storage system 400 according to various embodiments of the present invention. In various embodiments, the distributed storage system 400 is an erasure coded distributed storage system for storing multiple versions of data encoded by the method 100 described hereinbefore. The distributed storage system 400 comprises a plurality of secondary servers 402, each secondary server 402 configured to store codewords for multiple versions of a data object, and a group server 404 associated with the plurality of secondary servers 402. In the various embodiments, each secondary server 402 comprises a difference object generator module 302 configured to compute a difference between a version of the data object and a subsequent version of the data object to produce a difference object, and the group server 404 comprises a sparsity level determination module 304 configured to determine a sparsity level of the difference object received from the secondary server 402, a sparsity level comparator module 306 configured to determine whether the sparsity level satisfies a predetermined condition, a compression module 308 configured to compress the difference object to produce a compressed difference object, an erasure encoder 310 configured to encode the compressed difference object to produce a codeword for storing in the secondary server 402. In particular, the compression module 308 is configured to compress the difference object and the erasure encoder 310 is configured to encode the compressed difference object if the sparsity level is determined by the sparsity level comparator module 306 to satisfy the predetermined condition.

In various embodiments, the distributed storage system 400 may further comprise a master server configured for facilitating communication between a client and a plurality of the group servers 404 for storing multiple versions of data in the plurality of secondary servers 402.

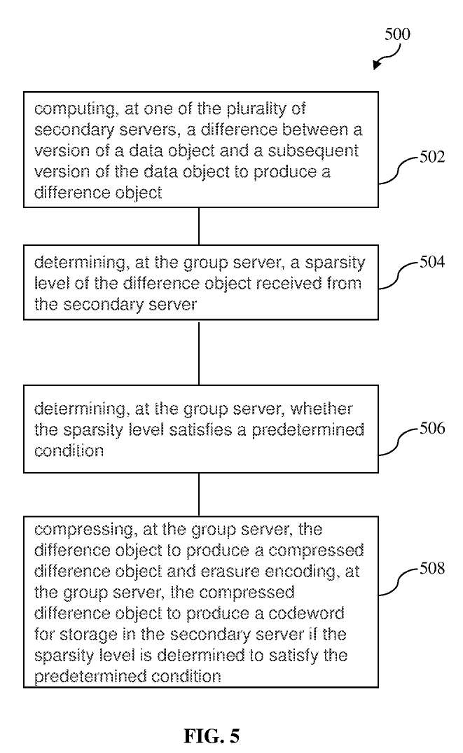

FIG. 5 depicts a flow diagram of a method 500 of storing multiple versions of data in a distributed storage system, such as the distributed storage system 400 as described above with reference to FIG. 4. The distributed storage system comprises a plurality of secondary servers 402 (e.g., chunk server), each secondary server 402 configured to store codewords for multiple versions of a data object, and a group server 404 associated with the plurality of secondary servers 402. The method 500 comprises a step 502 of computing, at one of the plurality of secondary servers 402, a difference between a version of a data object and a subsequent version of the data object to produce a difference object, a step 504 of determining, at the group server 404, a sparsity level of the difference object received from the secondary server 402, a step 506 of determining, at the group server 404, whether the sparsity level satisfies a predetermined condition, and a step 508 of compressing, at the group server 404, the difference object to produce a compressed difference object and erasure encoding, at the group server 404, the compressed difference object to produce a codeword for storage in the secondary server 402 if the sparsity level is determined to satisfy the predetermined condition.

A computing system or a controller or a microcontroller or any other system providing a processing capability can be presented according to various embodiments in the present disclosure. Such a system can be taken to include a processor. For example, each node or server of the distributed storage system described herein may include a processor/controller and a memory which are for example used in various processing carried out in the server as described herein. A memory used in the embodiments may be a volatile memory, for example a DRAM (Dynamic Random Access Memory) or a non-volatile memory, for example a PROM (Programmable Read Only Memory), an EPROM (Erasable PROM), EEPROM (Electrically Erasable PROM), or a flash memory, e.g., a floating gate memory, a charge trapping memory, an MRAM (Magnetoresistive Random Access Memory) or a PCRAM (Phase Change Random Access Memory).

In various embodiments, a “circuit” may be understood as any kind of a logic implementing entity, which may be special purpose circuitry or a processor executing software stored in a memory, firmware, or any combination thereof. Thus, in an embodiment, a “circuit” may be a hard-wired logic circuit or a programmable logic circuit such as a programmable processor, e.g. a microprocessor (e.g. a Complex Instruction Set Computer (CISC) processor or a Reduced Instruction Set Computer (RISC) processor). A “circuit” may also be a processor executing software, e.g. any kind of computer program, e.g. a computer program using a virtual machine code such as e.g. Java. Any other kind of implementation of the respective functions which will be described in more detail below may also be understood as a “circuit” in accordance with various alternative embodiments. Similarly, a “module” may be a portion of a system according to various embodiments in the present invention and may encompass a “circuit” as above, or may be understood to be any kind of a logic-implementing entity therefrom.

Some portions of the present disclosure are explicitly or implicitly presented in terms of algorithms and functional or symbolic representations of operations on data within a computer memory. These algorithmic descriptions and functional or symbolic representations are the means used by those skilled in the data processing arts to convey most effectively the substance of their work to others skilled in the art. An algorithm is here, and generally, conceived to be a self-consistent sequence of steps leading to a desired result. The steps are those requiring physical manipulations of physical quantities, such as electrical, magnetic or optical signals capable of being stored, transferred, combined, compared, and otherwise manipulated.

Unless specifically stated otherwise, and as apparent from the following, it will be appreciated that throughout the present specification, discussions utilizing terms such as “scanning”, “calculating”, “determining”, “replacing”, “generating”, “initializing”, “outputting”, or the like, refer to the action and processes of a computer system, or similar electronic device, that manipulates and transforms data represented as physical quantities within the computer system into other data similarly represented as physical quantities within the computer system or other information storage, transmission or display devices.

The present specification also discloses apparatus for performing the operations of the methods. Such apparatus may be specially constructed for the required purposes, or may comprise a general purpose computer or other device selectively activated or reconfigured by a computer program stored in the computer. The algorithms and displays presented herein are not inherently related to any particular computer or other apparatus. Various general purpose machines may be used with programs in accordance with the teachings herein. Alternatively, the construction of more specialized apparatus to perform the required method steps may be appropriate.

In addition, the present specification also implicitly discloses a computer program or software/functional module, in that it would be apparent to the person skilled in the art that the individual steps of the methods described herein may be put into effect by computer code. The computer program is not intended to be limited to any particular programming language and implementation thereof. It will be appreciated that a variety of programming languages and coding thereof may be used to implement the teachings of the disclosure contained herein. Moreover, the computer program is not intended to be limited to any particular control flow. There are many other variants of the computer program, which can use different control flows without departing from the spirit or scope of the invention. It will be appreciated to a person skilled in the art that various modules described herein (e.g., difference objection generator module 302, sparsity level determination module 304, sparsity level comparator module 306, compression module 308, and erasure encoder module 310) may be software module(s) realized by computer program(s) or set(s) of instructions executable by a computer processor to perform the required functions, or may be hardware module(s) being functional hardware unit(s) designed to perform the required functions. It will also be appreciated that a combination of hardware and software modules may be implemented.

Furthermore, one or more of the steps of the computer program or method may be performed in parallel rather than sequentially. Such a computer program may be stored on any computer readable medium. The computer readable medium may include storage devices such as magnetic or optical disks, memory chips, or other storage devices suitable for interfacing with a general purpose computer. The computer program when loaded and executed on such a general-purpose computer effectively results in an apparatus that implements the steps of the methods described herein.

In various embodiments, there is provided a computer program product, embodied in one or more computer-readable storage mediums, comprising instructions (e.g., difference objection generator module 302, sparsity level determination module 304, sparsity level comparator module 306, compression module 308, and erasure encoder module 310) executable by one or more computer processors to perform a method 100 of encoding multiple versions of data as described hereinbefore with reference to FIG. 1.

The software or functional modules described herein may also be implemented as hardware modules. More particularly, in the hardware sense, a module is a functional hardware unit designed for use with other components or modules. For example, a module may be implemented using discrete electronic components, or it can form a portion of an entire electronic circuit such as an Application Specific Integrated Circuit (ASIC). Numerous other possibilities exist. Those skilled in the art will appreciate that the system can also be implemented as a combination of hardware and software modules.

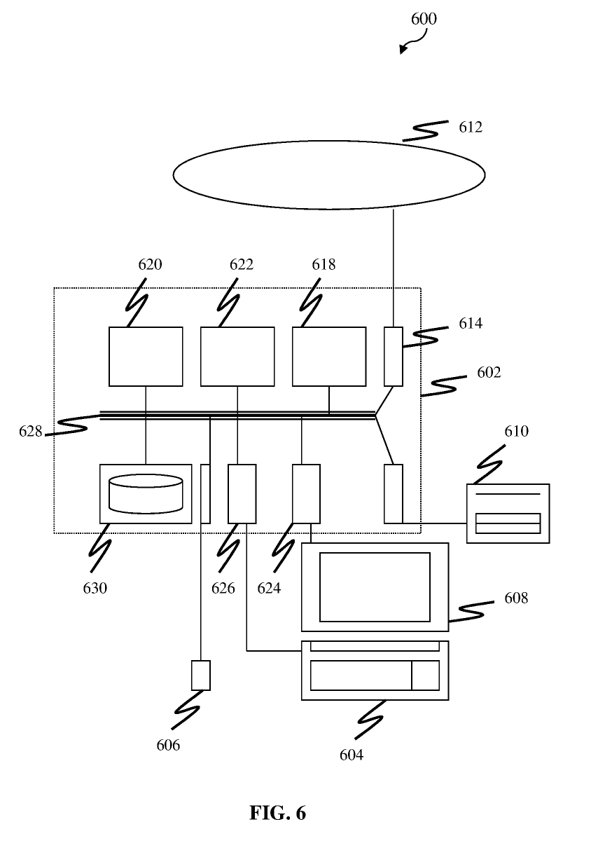

The methods or functional modules of the various example embodiments as described hereinbefore may be implemented on a computer system, such as a computer system 600 as schematically shown in FIG. 6 as an example only. The method or functional module may be implemented as software, such as a computer program being executed within the computer system 600, and instructing the computer system 600 to conduct the method of various example embodiments. The computer system 600 may comprise a computer module 602, input modules such as a keyboard 604 and mouse 606 and a plurality of output devices such as a display 608, and a printer 610. The computer module 602 may be connected to a computer network 612 via a suitable transceiver device 614, to enable access to e.g. the Internet or other network systems such as Local Area Network (LAN) or Wide Area Network (WAN). The computer module 602 in the example may include a processor 618 for executing various instructions, a Random Access Memory (RAM) 620 and a Read Only Memory (ROM) 622. The computer module 602 may also include a number of Input/Output (I/O) interfaces, for example I/O interface 624 to the display 608, and I/O interface 626 to the keyboard 604. The components of the computer module 602 typically communicate via an interconnected bus 628 and in a manner known to the person skilled in the relevant art.

It will be appreciated to a person skilled in the art that the terminology used herein is for the purpose of describing various embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In order that the present invention may be readily understood and put into practical effect, various example embodiments of the present inventions will be described hereinafter by way of examples only and not limitations. It will be appreciated by a person skilled in the art that the present invention may, however, be embodied in various different forms and should not be construed as limited to the example embodiments set forth hereinafter. Rather, these example embodiments are provided so that this disclosure will be thorough and complete, and will fully convey the scope of the present invention to those skilled in the art.

As described hereinbefore according to various embodiments of the present invention, there is provided a DEC/SEC method for reliable and efficient storage of multiple versions of data. If and when updates are sparse (i.e., differences between two successive versions have few non-zero entries), the method of encoding multiple version of data according to various embodiments advantageously exploits the sparsity using compressed sensing techniques applied with erasure coding. As will be discussed later according to example embodiments of the present invention, the method can provide significant reductions in the storage overheads whereby experiments with synthetic workloads were found to yield about 20-70% storage savings even for 10-20 versions of data with many non-sparse updates. In addition to developing the DEC, various methods/techniques have been developed according to example embodiments of the present invention taking into account practicality. The various techniques include optimizations to ameliorate the I/O penalty for accessing a single intermediate or the latest version, and a two-level DEC where only one measurement matrix is employed to store different levels of sparse objects, to facilitate a simple implementation while still enjoying significant storage gain benefits. In particular, it will be demonstrated through exemplary experiments that such techniques may ameliorate the drawbacks adequately without compromising the gains, thus improving the practicality of the methods/techniques of encoding multiple versions of data.

### System Model for Version Management

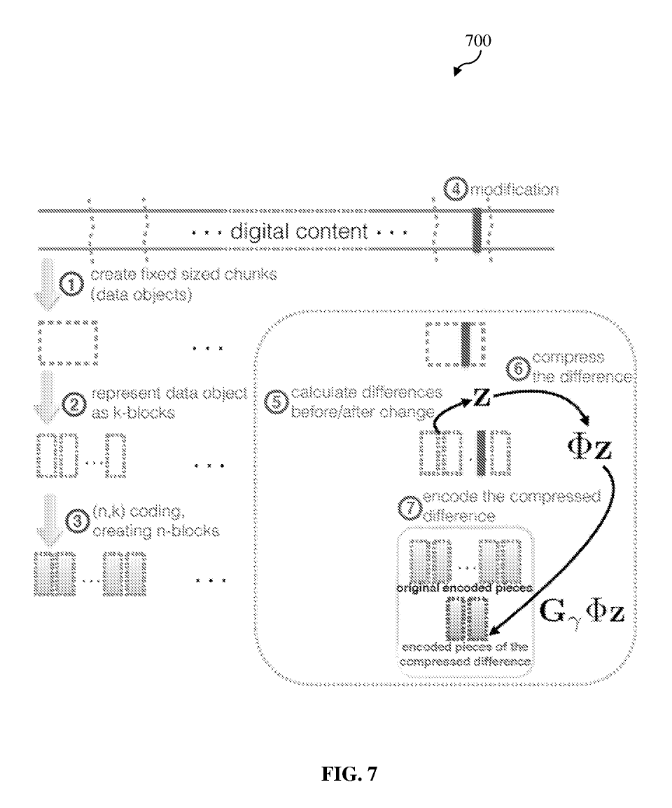

FIG. 7 depicts a schematic diagram illustrating an overview 700 of a method of encoding multiple versions of data according to various example embodiments of the present invention. Any digital content to be stored, be it a file, directory, database, or a whole filesystem, is divided into data chunks, shown as stage/phase 1 in FIG. 7. The coding techniques are agnostic of the nuances of the upper levels, and all discussions hereinafter will be at the granularity of the data chunks unless stated otherwise. The data chunks may also be referred to herein as data objects or just objects.

Formally, a data object to be stored over a network is denoted by XεF_{q}^{k}, that is, the data object is seen as a vector of k blocks (phase 2 in FIG. 7) taking value in the alphabet F_{q}, with F_{q} the finite field with q elements, q a power of 2 typically. Encoding for archival of an object x across n nodes is done (phase 3 in FIG. 7) using an (n,k) linear code, that is x is mapped to the codeword:

c=GxεF_{q}^{k},n>k, (Equation 1)

for G an n×k generator matrix with coefficients in F_{q}. The term systematic may be used to refer to a codeword C whose k first components are x, that is cᵢ=xᵢ, i=1, . . . , k. The above described what is a standard encoding procedure used in erasure coding based storage systems. Suppose next that the content mutates, and it is desired to store all versions.

Let x₁εF_{q}^{k} be the first version of a data object to be stored. When it is modified (phase 4 in FIG. 7), a new version x₂εF_{q}^{k} of the data object is created. More generally, a new version xⱼ₊₁ is obtained from xⱼ₊₁ to produce over time a sequence {xⱼεF_{q}^{k}, j=1, 2, . . . , L<∞} of L different versions of a data object, to be stored in the network. The application level semantic of the modifications is not of concern herein, but the bit level changes in the object is the area of interest in various embodiments of the present invention. Thus the changes between two successive versions may be captured by the following relation:

xⱼ₊₁=xⱼzⱼ₊₁, (Equation 2)

where zⱼ₊₁εF_{q}^{k} denotes the modifications (in phase 5 in FIG. 7) of the jth update. It is assumed for simplicity in various example embodiments that the changes do not affect the object length k. However, other example embodiments will be described later whereby zero padding is used to promote sparsity between versions of data object and enable the encoding method to handle changes in the length/size of the file contents in the data object between versions of the data object.

An important factor in various example embodiments is that when the changes from xⱼ to xⱼ₊₁ are small (decided by the sparsity of zⱼ₊₁), compressed sensing is applied which permits to represent a k-length γ-sparse vector z (see Definition 1 below) with less than k components (phase 6 in FIG. 7) through a linear transformation on x, which does not depend on the position of the non-zero entries, in order to gain in storage efficiency.

Definition 1: For some integer 1≦γ<k, a vector zεF_{q}^{k} is said to be γ-sparse if it contains at most γ non-zero entries.

Let zεF_{q}^{k} be γ-sparse such that

$$γ < \frac{k}{2} ,$$

and ΦεF_{q}^{2γ×k} denote the measurement matrix used for compressed sensing. The compressed representation z′εF_{q}^{2γ} of z is obtained as

z′=Φz, (Equation 3)

According to various example embodiments, the following proposition gives a sufficient condition on Φ to uniquely recover z from z′ using a syndrome decoder.

Proposition 1: If any 2γ columns of Φ are linearly independent, the γ-sparse vector z can be recovered from z′.

Once sparse modifications are compressed, which reduces the I/O reads, they are encoded into codewords of length <n (phase 7 in FIG. 7) decreasing in turn the storage overhead.

### Differential Erasure Encoding for Version-Control

A method of encoding multiple versions of data will now be described according to various example embodiments. Let {xⱼεF_{q}^{k}, 1≦j≦L} be the sequence of versions of a data object to be stored. The changes from xⱼ to xⱼ₊₁ are reflected in the vector zⱼ₊₁=xⱼ₊₁−xⱼ in Equation (2) which is γⱼ₊₁-sparse (see Definition 1) for some 1≦γⱼ₊₁≦k. The value γⱼ₊₁ may a priori vary across versions of one object, and across application domains. All the versions x₁, . . . , x_{L} need protection from node failures, and are archived using a linear erasure code (see Equation (1)).

### Object Encoding

A generic differential encoding (also referred to as Step j+1) suited for efficient archival of versioned data, which exploits the sparsity of updates, when

$${γ}_{j + 1} \leq \frac{k}{2}$$

to reduce the storage overheads of archiving all the versions reliably. In various example embodiments, it is assumed that one storage node is in possession of two versions, say xⱼ and xⱼ₊₁ of one data object, jᵢ=1, . . . , L−1. The corresponding implementation will be discussed later under Implementation and Placement.

Step j+1. Two versions of xⱼ and xⱼ₊₁ are located in one storage node. The difference vector zⱼ₊₁=xⱼ₊₁−xⱼ and the corresponding sparsity level γⱼ₊₁ are computed. If

$${γ}_{j + 1} \geq \frac{k}{2} ,$$

the object zⱼ₊₁ is encoded as cⱼ₊₁=Gzⱼ₊₁. On the other hand, if

$${γ}_{j + 1} < \frac{k}{2} ,$$

then zⱼ₊₁ is first compressed (see Equation (3)) as z′ⱼ₊₁=Φ_{γ}_{ⱼ₊₁}, where Φ_{γ}_{ⱼ₊₁}εF_{q}^{2γ}^{ⱼ₊₁}^{×k} is a measurement matrix such that any 2γⱼ₊₁ of its columns are linearly independent (see Proposition 1). Subsequently, zⱼ₊₁′ is encoded as cⱼ₊₁=Gγⱼ₊₁zⱼ₊₁′, where G_{γ}_{ⱼ₊₁}εF_{q}ⁿ^{_{γj+1}}^{×2γ}^{ⱼ₊₁} is the generator matrix of an (n_{γ}_{ⱼ₊₁},2γⱼ₊₁) erasure code with storage overhead κ. The components of cⱼ₊₁ are distributed across a set of Nⱼ₊₁ of n_{γ}_{ⱼ₊₁} nodes, whose choice will be discussed later below.
Since γⱼ₊₁ is random, a total of

$$⌈ \frac{k}{2} ⌉$$

erasure codes denoted by

$$G = \{ G , {G}_{1} , … , {G}_{⌈ \frac{k}{2} ⌉ - 1} \} ,$$

and a total of

$$⌈ \frac{k}{2} ⌉ - 1$$

measurement matrices denoted by

$$\sum = \{ {Φ}_{1} , {Φ}_{2} , … , {Φ}_{⌈ \frac{k}{2} ⌉ - 1} \}$$

have to be designed a priori. The erasure codes may be taken systematic and/or MDS (Maximum Distance Separable) (that is, such that any n−k failure patterns are tolerated), the encoding method according to various example embodiments works irrespectively of these choices. This encoding strategy implies one extra matrix multiplication whenever a sparse difference vector is obtained. An example will now be provided to illustrate the computations.

### Example 1

Take k=4, suppose that the digital content is written in binary as (100110010010) and that the linear code used for storage is a (6, 4) code over F₈. To create the first data object x₁, cut the digital content into k=4 chunks 100, 110, 010, 010, so that x₁ is written over F₈ as x₁=(1,1+w, w, w) where w is the generator of F₈*, satisfying w³=w+1. The next version of the digital content is created, say (100110110010). Similarly, x₂ becomes x₂=(1,1+w,1+w,w), and the difference vector z₂ is given by z₂=x₂x₁=(0,0,1,0), with γ₂=1<k/2. Apply a measurement matrix Φ_{γ}_{₂}=Φ₁ to compress z₂:

$${Φ}_{1} {z}_{2} = [ \begin{matrix}1 & 0 & w & w + 1 \\ 0 & 1 & w + 1 & w\end{matrix} ] [ \begin{matrix}0 \\ 0 \\ 1 \\ 0\end{matrix} ] = [ \begin{matrix}w \\ w + 1\end{matrix} ] = {z}_{2}^{′}$$

Note that every two columns of Φ₁ are linearly independent (see Proposition 1 above), thus allowing the compressed vector to be recovered. Encode z₂′ using a single parity check code:

$${c}_{2} = [ \begin{matrix}1 & 0 \\ 0 & 1 \\ 1 & 1\end{matrix} ] [ \begin{matrix}w \\ w + 1\end{matrix} ] = [ \begin{matrix}w \\ w + 1 \\ 1\end{matrix} ]$$

### Implementation and Placement

Caching.

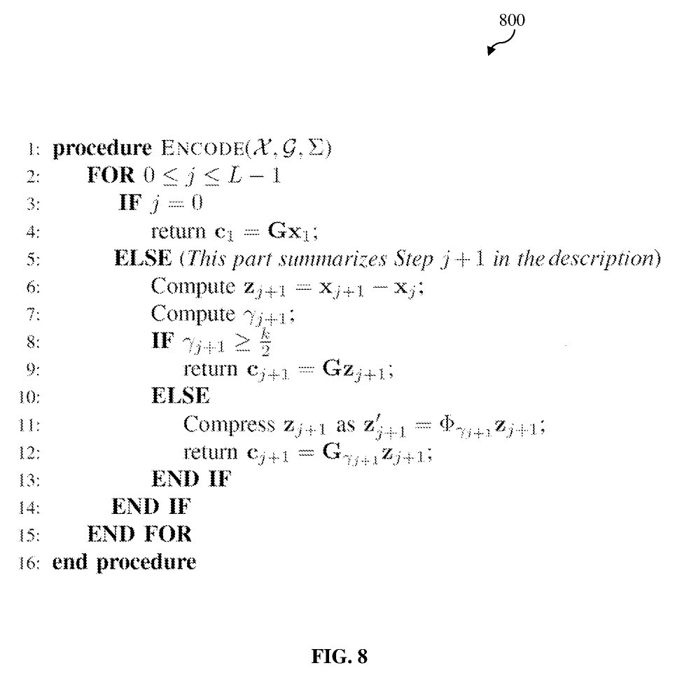

To store xⱼ₊₁ for j≧1, the encoding method according to various example embodiments requires the calculation of differences between the existing version xⱼ and the new version xⱼ₊₁ in Equation (2). However, it does not store xⱼ, but x₁ together with z₂, . . . , zⱼ. Reconstructing xⱼ before computing the difference and encoding the new difference is expensive in terms of I/O operations, network bandwidth, latency as well as computations. To address this issue, according to various example embodiments, a full copy of the latest version xⱼ is cached until a new version xⱼ₊₁ arrives. This also helps in improving the response time and overheads of data read operations in general, and thus disentangles the system performance from the storage efficient resilient storage of all the versions. Considering caching as a practical method, FIG. 8 shows an algorithm 800 which summarizes the differential erasure coding procedure according to various example embodiments of the present invention. The input and the output of the algorithm are χ={x₁εF_{q}^{k}, 1≦j≦L} and {cⱼ, 1≦j≦L}, respectively.

Placement Consideration.

The choice of the sets Nⱼ₊₁, j=0, . . . , L−1 of nodes over which the different versions are stored needs a closer introspection. Since x₁ together with z₂, . . . , zⱼ are needed to recover x₁, if x₁ is lost, xⱼ cannot be recovered, and thus there is no gain in fault tolerance by storing xⱼ in a different set of nodes than N₁. Furthermore, since n_{γ}_{ⱼ}<n, codewords cᵢs may have different resilience to failures. The dependency of xⱼ on previous versions suggests that the fault-tolerance of subsequent versions are determined by the worst fault-tolerance achieved among cᵢs for i<j.

### Example 2

Continuing from Example 1, where x₁ is encoded into c₁=(c₁₁, . . . , c₁₆) using a (6, 4) MDS code. Allocate c₁ᵢ to Nᵢ, that is use the set N₁={N₁, . . . , N₆} of nodes. Store c₂ in N₂={N₁, N₂, N₃}⊂N₁ for collocated placement, and N₂={N₁′,N₂′,N₃′},N₂∩N₁=Ø for distributed placement. Let p be the probability that a node fails, and failures are assumed independent. The probability to recover both x₁ and x₂ in case of node failures (known as static resilience) for both distributed and collocated strategies will be computed below.

For distributed placement, the set of error events for losing x₁ is ε={3 or more nodes fail in N₁}. Hence, the probability Prob{ε₁} of losing x₁ is given by

p⁶+C₅⁶p⁵(1−p)+C₄⁶p⁴(1−p)²+C₃⁶p³(1−p)³, (Equation 4)

where Cᵣ^{m} denotes the m choose r operation. The set of error events for losing z₂ stored with a (3, 2) MDS code is ε₂={2 or 3 nodes fail in N₂}. Thus, z₂ is lost with probability

Prob(ε₂)=p³+C₂³p²(1−p), (Equation 5)

Equations (4) and (5), the probability of retaining both versions is

Prob_{d}(x₁,x₂) [symbol] (1−Prob(ε₁))(1−Prob(ε₂)), (Equation 6)

The set of error events for losing x₁ or z₂ is:

ε₁∪ε₂={3 or more nodes fail}∪{specific 2 nodes failure}

for collocated placement. Out of C₂⁶ possible 2 node failure patterns, 3 patterns contribute to the loss of the object z₂. Therefore, Prob(ε₁∪ε₂) is:

p⁶+C₅⁶p⁵(1+p)+C₄⁶p⁴ (1+p)²+C₃⁶p³ (1+p)³+3p² (1+p)⁴ from which, the probability of retaining both the versions is:

Prob_{c}(x₁,x₂) [symbol] 1−Prob(ε₁∪ε₂), (Equation 7)

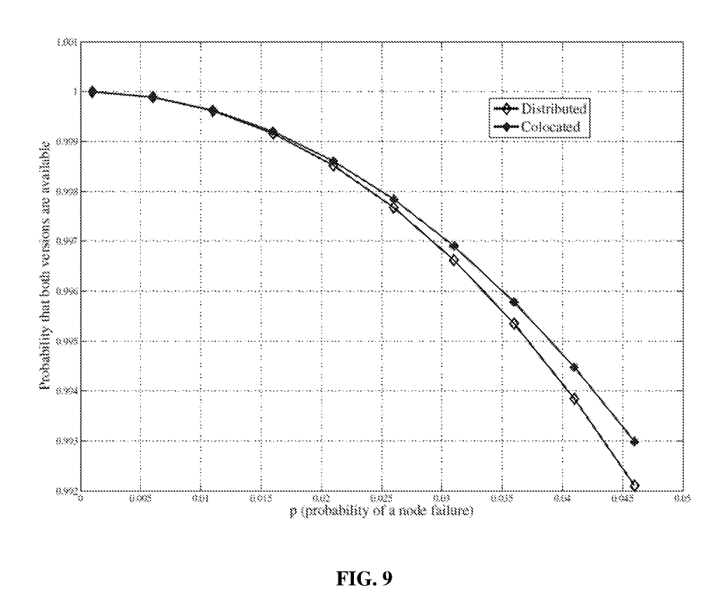

FIG. 9 depicts plots comparing the probability that both versions are available. More specifically, in FIG. 9, Equations 6 and 7 are compared for different values of p from 0.001 to 0.05. The plot shows that collocated allocation results in better resilience than the distributed case.

Optimized Step j+1.

Based on the above derivations and observations, the generic differential encoding (Step j+1) is modified according to various example embodiments of the present invention as: if

$${γ}_{j + 1} \geq \frac{k}{2} , {z}_{j + 1}$$

is discarded and xⱼ₊₁ is encoded as cⱼ₊₁=Gxⱼ₊₁ to ensure that a whole version is again encoded. Since many contiguous sparse versions may be created, according to various example embodiments, an iteration threshold i may be imposed after which even if all differences from one version to another stay very sparse, a whole version is used for coding and storage.

### On the Storage Overhead

Since employed erasure codes depend on the sparsity level, the storage overhead of the above differential encoding improves upon that of encoding different versions independently. The average gains in storage overhead will be discussed later below. Formally, the total storage size till the l-th version is:

$$δ ( {x}_{1} , {x}_{2} , … , {x}_{l} ) = n + {\sum }_{j = 2}^{l} min ( 2 κ {γ}_{j} , n ) \leq ln ,$$

for 2≦l<L. The storage overhead for the above-described Optimized Step j+1 is the same as that of Step j+1 since for

$${γ}_{j + 1} \geq \frac{k}{2} ,$$

the coded objects Gx_{J+1} and Gz_{J+1} have the same size.

### Object Retrieval

Suppose that L versions of a data object are archived using Step j+1, j≦L−1 and the user needs to retrieve some xₗ, 1<l≦L. Assuming that there are enough encoded blocks for each cᵢ (i≦l) available, relevant nodes in the sets N₁, . . . , Nₗ are accessed to fetch and decode the cᵢ to obtain x₁, and the l−1 compressed differences z₂′, z₃′ . . . , zₗ′. As discussed hereinbefore on placement and an illustration that reusing the same set of nodes gives the best availability with MDS codes, hence bounding the number of accessed nodes by |N₁|. All compressed differences sharing the same sparsity can be added first, and then decompressed, since

$${\sum }_{i ∈ {J}_{r}} {z}_{i}^{′} = {Φ}_{γ} {\sum }_{i ∈ {J}_{γ}} {z}_{i}$$

for J_{γ}={j|γⱼ=γ}. The cost of recovering Σ_{iεJ}_{_{γ}}zᵢ is only one decompression instead of |J_{γ}|, with which xₗ is given by:

$${x}_{l} = {x}_{1} + {\sum }_{j = 2}^{l} {z}_{i}$$

A minimum of k I/O reads is needed to retrieve x₁. For zⱼ (2≦j<l), the number of I/O reads may be lower than k, depending on the update sparsity. If

$${γ}_{j} < \frac{k}{2} ,$$

then zⱼ′ is retrieved with 2γⱼ I/O reads, while if

$${γ}_{j} \geq \frac{k}{2} ,$$

then zⱼ′ is recovered with k I/O reads, so that min(2γⱼ, k) I/O reads are needed for zⱼ. The total number of I/O reads to retrieve xₗ is:

$$η ( {x}_{l} ) = k + {\sum }_{j = 2}^{l} min ( 2 {γ}_{j} , k ) , \qquad ( Equation 8 )$$

and so is the total number of I/O reads to retrieve the first l versions: η(x₁, x₂, . . . , xₗ)=η(xₗ).

To retrieve xₗ for 1≦l≦L, when archival was done using Optimized Step j+1, j≦L−1, look for the most recent version xₗ′ such that l′≦l and

$${γ}_{{l}^{′}} \geq \frac{k}{2} .$$

Then, using {x_{l′}, z_{l′+1}, . . . , zₗ}, the object xₗ is reconstructed as xₗ=x_{l′}+Σ_{j=l′+1}^{l} zⱼ. Hence, the total number of I/O reads is:

$$η ( {x}_{l} ) = k + {\sum }_{j = {l}^{′} + 1}^{l} min ( 2 {γ}_{j} , k ) . \qquad ( Equation 9 )$$

The number of I/O reads to retrieve the first l versions is the same as for Step j+1.

The benefits of the differential encoding as presented above in terms of average number of I/O reads will be discussed later below.

### Example 3

Assume that L=20 versions of an object of size k=10 are differentially encoded, with sparsity profile {γⱼ, 2≦j≦L}={3, 8, 3, 6, 7, 9, 10, 6, 2, 2, 3, 9, 3, 9, 3, 10, 4, 2, 3}. The storage pattern is {x₁, z₂, z₃, . . . , z₂₀}. Assuming x₁ is not sparse, the I/O read numbers to access {x₁, z₂, z₃, . . . , z₂₀} are {10, 6, 10, 6, 10, 10, 10, 10, 10, 4, 4, 6, 10, 6, 10, 6, 10, 8, 4, 6}. The total I/O reads to recover all the 20 versions is 156 (instead of 200 for the non-differential method). The total storage space for all the 20 versions assuming a storage overhead of 2 is 312 (instead of 400 otherwise). The I/O read numbers to recover {x₁, x₂, x₃ . . . , x₂₀} are {10, 16, 26, 32, 42, 52, 62, 72, 82, 86, 90, 96, 106, 112, 122, 128, 138, 146, 150, 156}, while for the Optimized Step, the I/O read numbers are {10, 16, 10, 16, 10, 10, 10, 10, 10, 14, 18, 24, 10, 16, 10, 16, 10, 18, 22, 28}.

### Reverse Differential Erasure Coding

The total storage size and the number of I/O reads required by the differential methods (forward differential and reverse differential) are summarized in Table I below.

TABLE I
I/O Access Metrics for the Traditional
and the Differential Methods to Store

| | | Forward | Reverse |
|---|---|---|---|
| Parameter | Traditional | Differential | Differential |
| I/O reads to read | k | k + Σⱼ₌₂^{l} | k |
| the l-th version | | min(2γⱼ, k) | |
| I/O reads to read | lk | k + Σⱼ₌₂^{l} | k + Σⱼ₌₂^{l} |
| the first l-th | | min(2γⱼ, k) | min(2γⱼ, k) |
| versions | | | |
| Number of | 1 (on the | 1 (on the latest | 2 (on the latest |
| Encoding | latest version) | version) | and the preceding |
| Operations | | | versions) |
| Total Storage Size | ln | n + Σⱼ₌₂^{l} | n + Σⱼ₌₂^{l} |
| till the l-th version | | min(2κγⱼ, n) | min(2κγⱼ, n) |

{x₁, x₂, . . . , xₗ}
If some γⱼ, 1≦j≦l, are smaller than

$$\frac{k}{2} ,$$

then the number of I/O reads for joint retrieval of all the versions {x₁, x₂, . . . , xₗ} is lower than that of the traditional method. However, this advantage comes at the cost of higher number of I/O reads for accessing the l-th version xₗ alone. Therefore, for applications where the latest archived versions are more frequently accessed than the joint versions, the overhead for reading the latest version dominates the advantage of reading multiple versions. For such applications, a modified differential method which may be referred to as the reverse DEC is provided according to various example embodiments of the present invention, whereby the order of storing the difference vectors is reversed.

### Object Encoding

As described hereinbefore for the forward DEC, it is assumed that one node stores the latest version xⱼ and the new version xⱼ₊₁ of a data object. Since xⱼ is readily obtained, caching is less critical here.

Step j+1.

Compute the difference vector zⱼ₊₁=xⱼ₊₁−xⱼ and its sparsity level γⱼ₊₁. The object xⱼ₊₁ is encoded as cⱼ₊₁=Gxⱼ₊₁ and stored in Nⱼ₊₁. Furthermore, if

$${γ}_{j + 1} < \frac{k}{2} ,$$

then zⱼ₊₁ is first compressed as zⱼ₊₁′=Φ_{γ}_{ⱼ₊₁}zⱼ₊₁, and then encoded as c=G_{γ}_{ⱼ₊₁}zⱼ₊₁′, where G_{γ}_{ⱼ₊₁} is the generator matrix of an (n_{γ}_{ⱼ₊₁},2γⱼ₊₁) erasure code. Finally, the preceding version cⱼ=c.

A key feature is that in addition to encoding the latest version xⱼ₊₁, the preceding version is also re-encoded depending on the sparsity level γⱼ₊₁, resulting in two encoding operations (instead of one for the forward DEC as described hereinbefore).

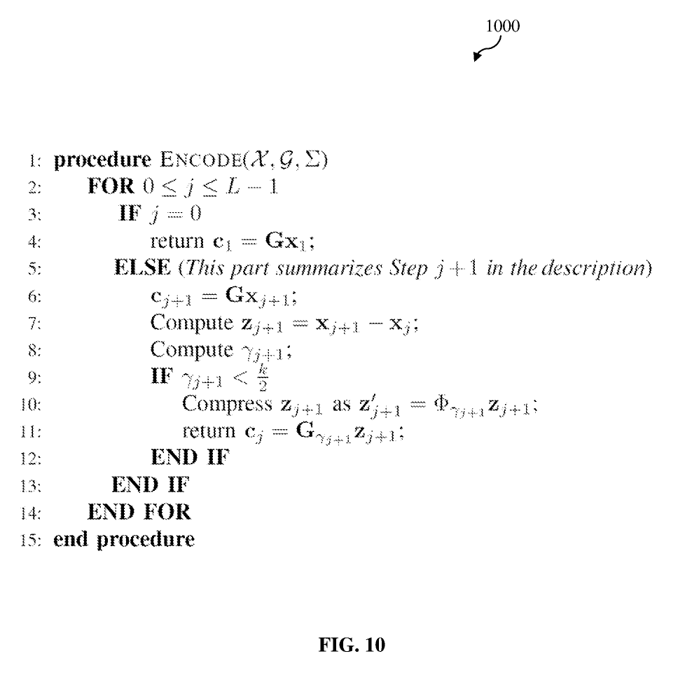

FIG. 10 shows an algorithm 1000 which summarizes the reverse DEC procedure according to various example embodiments of the present invention. The storage overhead for this reverse DEC is the same as for the forward DEC as described hereinbefore. Furthermore, the considerations on data placement and static resilience of cⱼ in the set Nⱼ of nodes are analogous as well, and an optimized version may be obtained similarly as for the forward DEC described hereinbefore. They will thus not be elaborated further for the reverse DEC for conciseness.

### Object Retrieval

Suppose that l versions of a data object have been archived, and the user needs to retrieve the latest version xₗ. In the reverse DEC, unlike for the forward DEC, the latest version xₗ is encoded as Gxₗ. Hence, the user must access a minimum of k nodes from the set Nₗ to recover xₗ. To retrieve all the l versions {x₁, x₂, . . . , xₗ}, the user accesses the nodes in the sets N₁, N₂, . . . , Nₗ to retrieve z₂′, z₃′, . . . , zₗ′, xₗ, respectively. The objects z₂, z₃ . . . , zₗ are recovered from z₂′, z₃′ . . . zₗ′, respectively through a sparse-reconstruction procedure, and xⱼ, 1≦j≦l−1, is recursively reconstructed as

$${x}_{j} = {x}_{l} - ( {\sum }_{t = j}^{l} {z}_{t} ) .$$

It is clear that a total of k+Σⱼ₌₂^{l} min(2γⱼ,k) reads are needed for accessing all the l versions and only k reads for the latest version. The performance metrics of the reverse DEC technique are also summarized in Table I above in the last column.

### Example 4

For the sparsity profile of Example 3, the storage pattern using reverse DEC is {z₂, z₃ . . . , z₂₀, x₂₀}. The I/O read numbers to access {z₂, z₃ . . . , z₂₀, x₂₀} are {6, 10, 6, 10, 10, 10, 10, 10, 4, 4, 6, 10, 6, 10, 6, 10, 8, 4, 6, 10}. The total storage size and the I/O reads to recover all the 20 versions are the same as that of the forward differential method. The I/O numbers to recover {x₁, x₂, x₃ . . . , x₂₀} are {156, 150, 144, 134, 124, 114, 104, 94, 84, 80, 76, 70, 60, 54, 44, 38, 28, 20, 16, 10}. Note that I/O number to access the latest version (in this case 20^{th} version) is lower than that of the forward differential method. For the optimized step, the corresponding I/O numbers are {16, 10, 16, 10, 10, 10, 10, 10, 24, 20, 16, 10, 16, 10, 16, 10, 28, 20, 16, 10}.

### Two-Level Differential Erasure Coding

The differential encoding (both forward and the reverse DEC) exploits the sparse nature of the updates to reduce the storage size and the number of I/O reads. Such advantages stem from the application of

$$⌈ \frac{k}{2} ⌉$$

erasure codes matching the different levels of sparsity

$$( ⌈ \frac{k}{2} ⌉ - 1$$

erasure codes for each

$$γ < \frac{k}{2}$$

and one for

$$γ \geq \frac{k}{2} ) .$$

If k is large, then the system needs a large number of erasure codes, which may be undesirable. To address or ameliorate this issue, according to various example embodiments of the present invention, a modified DEC is provided which employs only two erasure codes to achieve easier implementation. This modified DEC may be referred to as two-level DEC and the forward and reverse DEC described hereinabove according to various example embodiments of the present invention may be referred to as

$$\frac{k}{2}$$

level forward DEC and

$$\frac{k}{2}$$

level reverse DEC, or collectively as

$$\frac{k}{2}$$

level DEC. According to various example embodiments of the present invention, the following ingredients for the two-level DEC method may be required:
(1) An (n,k) erasure code with generator matrix GεF_{q}^{n×k} to store the original data object,
(2) A measurement matrix Φ_{T}εF_{q}^{2T×k} to compress sparse updates, where

$$T ∈ \{ 1 , 2 , … , ⌊ \frac{k}{2} ⌋ \}$$

is a chosen threshold, and
(3) An (n_{T},2T) erasure code with generator matrix G_{T} εF_{q}ⁿ^{_{T}}^{×2T} to store the compressed data object. The number of n_{T} is chosen such that

$$κ \frac{n}{k} = \frac{{n}_{T}}{2 T} .$$

The two-level forward DEC method will now be described below. It will be understood by a person skilled in the art that the two-level reverse DEC method can be obtained by modifying the two-level forward DEC method in the same or similar manner as how the

$$\frac{k}{2}$$

level reverse DEC was obtained by modifying the

$$\frac{k}{2}$$

level forward DEC method as described hereinbefore. Therefore, the two-level reverse DEC method will not be elaborated further for conciseness.

### Object Encoding

A key point of the two-level DEC is that the number of erasure codes (and the corresponding measurement matrices) to store the γ-sparse vectors for

$$1 \leq γ < \frac{k}{2}$$

is reduced from

$$⌈ \frac{k}{2} ⌉ - 1$$

to 1. Thus, based on the sparsity level, the update vector is either compressed and then archived, or archived as it is.

Step j+1.

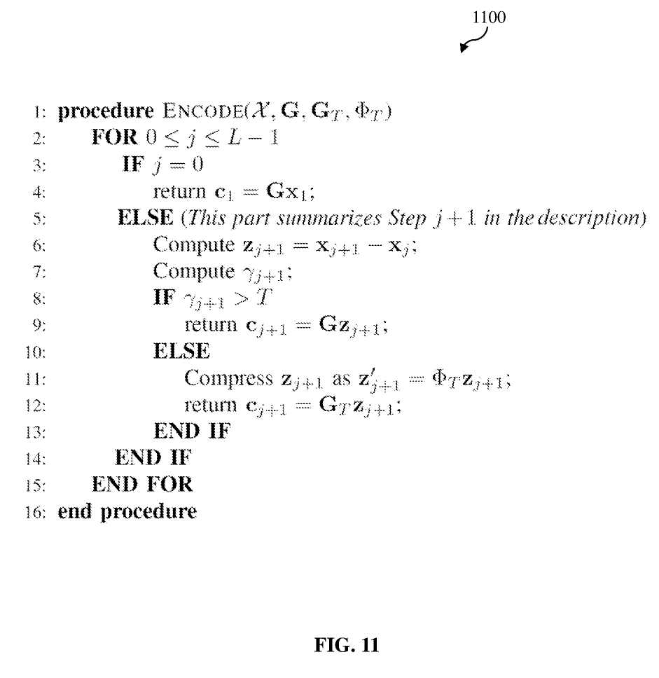

Once the version xⱼ₊₁ is created, using xⱼ in the cache, the difference vector zⱼ₊₁=xⱼ₊₁−xⱼ and the corresponding sparsity level γⱼ₊₁ are computed. If γⱼ₊₁>T, the object zⱼ₊₁ is encoded as cⱼ₊₁=Gzⱼ₊₁, else zⱼ₊₁ is first compressed (see Equation 3) as zⱼ₊₁′=Φ_{T}zⱼ₊₁, where the measurement matrix Φ_{T}εF_{q}^{2T×k} is such that any 2T of its columns are linearly independent (see Proposition 1). Then, zⱼ₊₁′ is encoded as cⱼ₊₁=G_{T} zⱼ₊₁′, where G_{T} εF_{q}ⁿ^{_{T}}^{×2T} is the generator matrix of an (n_{T},2T) erasure code. The components of cⱼ₊₁ are stored across the set Nⱼ₊₁ of nodes. FIG. 11 shows an algorithm 1100 which summarizes the above-described two-level forward DEC procedure according to various example embodiments of the present invention.

### On the Storage Overhead

The total storage size for the two-level DEC is δ(x₁, x₂, . . . , xₗ)=n+Σⱼ₌₂^{l}nⱼ, where

$${n}_{j} = \{ \begin{matrix}n , & if {γ}_{j} > T \\ κ 2 T , & otherwise\end{matrix} \qquad ( Equation 10 )$$

### Data Retrieval

### Similarly to the

$$\frac{k}{2}$$

level DEC method, the object xₗ for some 1≦l<L is reconstructed as xₗ=x₁+Σⱼ₌₂^{l}zⱼ, by accessing the nodes in the sets N₁, N₂, . . . , Nₗ. To retrieve x₁, a minimum of k I/O reads is needed. If zⱼ is γⱼ-sparse and γⱼ≦T, then zⱼ′ is first retrieved with 2T I/O reads, second, zⱼ is decoded from zⱼ′ and Φ_{T} through a sparse-reconstruction procedure. On the other hand, γⱼ>T, then zⱼ is recovered with k I/O reads. Overall, the total number of I/O reads for xₗ in the differential set up is η(xₗ)=k+Σⱼ₌₂^{l}nⱼ, where

$${n}_{j} = \{ \begin{matrix}2 T , & if {γ}_{j} \leq T \\ k , & otherwise\end{matrix} \qquad ( Equation 11 )$$

Similarly, the total number of I/O reads to retrieve the first/versions is also η(x₁, . . . , xₗ)=k+Σⱼ₌₂^{l}nⱼ.

### Example 5

A threshold T=3 is applied to the sparsity profile in Example 3 described hereinbefore. The object z₁₈ (with γ₁₈=4) is then archived without compression whereas all objects with sparsity lower than or equal to 3 are compressed using a 6×10 measurement matrix. The I/O read numbers to access {x₁, z₂, z₃ . . . , z₂₀} are {10, 6, 10, 6, 10, 10, 10, 10, 10, 6, 6, 6, 10, 6, 10, 6, 10, 10, 6, 6}. The total number of I/O reads to access all the versions is 164 and the corresponding storage size is 328. Thus, with just two levels of compression, the storage overhead is more than the 5-level DEC method but still lower than 400.

### Threshold Design Optimization

For the two-level DEC, the total number of I/O reads and the storage size are random variables that are respectively given by η=k+Σⱼ₌₂^{l}nⱼ, where ηⱼ is given in Equation 11 and δ=n+Σⱼ₌₂^{L}nⱼ, where ηⱼ is given in Equation 10. Note that η and δ are also dependent on the threshold T. The threshold T that minimizes the average values of η and δ is given by:

$${T}_{opt} = arg { min}_{T ∈ \{ 1 , 2 , … , ⌊ \frac{k}{2} ⌋ \}} wE [ δ ( {x}_{1} , {x}_{2} ) ] + ( 1 - w ) E [ η ( {x}_{1} , {x}_{2} ) ] , \qquad ( Equation 12 )$$

where 0≦w≦1 is a parameter that appropriately weights the importance of storage overhead and I/O reads overhead, and E[•] is the expectation operator over the random variables {Γ₂, Γ₃, . . . , Γ_{L}}. This optimization depends on the underlying probability mass functions (PMFs) on {Γⱼ}, so the choice of the parameter

$$1 \leq T \leq ⌊ \frac{k}{2} ⌋$$

will be described later below.

### Cauchy Matrices for Two-Level DEC

Suppose that Φ_{T} εF_{q}^{2T×k} is carved from a Cauchy matrix. A Cauchy matrix is such that any square submatrix is full rank. Thus, there exists a 2γⱼ×k submatrix Φ_{T} ε(I_{2γ}_{ⱼ},:) of Φ_{T}, where I_{2γ}_{ⱼ}⊂{1, 2, . . . , 2T} represents the indices of 2γⱼ rows, for which any 2γⱼ columns are linearly independent, implying that the observations r=Φ_{T}(I_{2γ}_{ⱼ},:)zⱼ, can be retrieved from with 2γⱼ I/O reads. Also, using r and Φ_{T}(I_{2γ}_{ⱼ},:)z₁, the sparse update zⱼ can be decoded through a sparse-reconstruction procedure. Thus, the number of I/O reads to get zⱼ is reduced from 2T to 2γⱼ when γⱼ≦T. This procedure is applicable for any γⱼ<T. Therefore, a γⱼ-sparse vector with γⱼ≦T can be recovered with 2γⱼ I/O reads. The total number of I/O reads for xₗ in the two-level DEC with Cauchy matrix is finally η(xₗ)=k+Σⱼ₌₂^{l}nⱼ, where:

$${n}_{j} = \{ \begin{matrix}2 {γ}_{j} , & if {γ}_{j} \leq T \\ k , & otherwise\end{matrix} \qquad ( Equation 13 )$$

Since the number of I/O reads is potentially different compared to the case without Cauchy matrices, the threshold design optimization in Equation 12 can result in different answers for this case. This optimization will be discussed later below under simulation results.

### Example 6

With Cauchy matrix for Φ_{T} in Example 5, the I/O numbers to access {z₂, z₃ . . . , z₂₀, x₂₀} are {10, 6, 10, 6, 10, 10, 10, 10, 10, 4, 4, 6, 10, 6, 10, 6, 10, 10, 4, 6}, which makes the total number of I/O reads 158. However, the total storage size with Cauchy matrix continues to be 328.

### Simulation Results

Experimental results on the storage size and the number of I/O reads for different encoding methods will now be presented and discussed. It is assumed that {Γⱼ,2≦j≦L} is a set of random variables and its realizations {γⱼ, 2≦j≦L} are known. First, a version-control system with L=2 is considered, which is the worst-case choice of L as more versions could reveal more storage savings. This setting both serves as a proof of concept, and shows the storage savings for this simple case. Subsequently, experimental results are also presented for a setup with L>2 versions.

System with L=2 Versions

For L=2, there is one random variable denoted henceforth as Γ, with realization γ. Since Γ is a discrete random variable with finite support, the following finite support distributions are tested for the experimental results on the average number of I/O reads for the two versions and the average storage size.

Binomial Type PMF:

This is a variation of the standard Binomial distribution given by

$${P}_{Γ} ( γ ) = c \frac{k !}{γ ! ( k - γ ) !} {{p}^{γ} ( 1 - p )}^{k - γ} , γ = 1 , 2 , … , k , \qquad ( Equation 14 )$$

where

$$c = \frac{1}{1 - {( 1 - p )}^{k}}$$

is the normalizing constant. The change is necessary since γ=0 is not a valid event.

Truncated Exponential PMF:

This is a finite support version of the exponential distribution in parameter α>0:

P_{Γ}(γ)=ce^{-αγ}. (Equation 15)

The constant c is chosen such that Σ_{γ=1}^{k}P_{Γ}(γ)=1.

Truncated Poisson PMF:

This is a finite support version of the Poisson distribution in parameter λ given by:

$${P}_{Γ} ( γ ) = c \frac{{λ}^{γ} {e}^{- λ}}{γ !} , \qquad ( Equation 16 )$$

where the constant c is chosen such that Σ_{γ=1}P_{Γ}(γ)=1.

Uniform PMF:

This is the standard uniform distribution:

$${P}_{Γ} ( γ ) = \frac{1}{k} . \qquad ( Equation 17 )$$

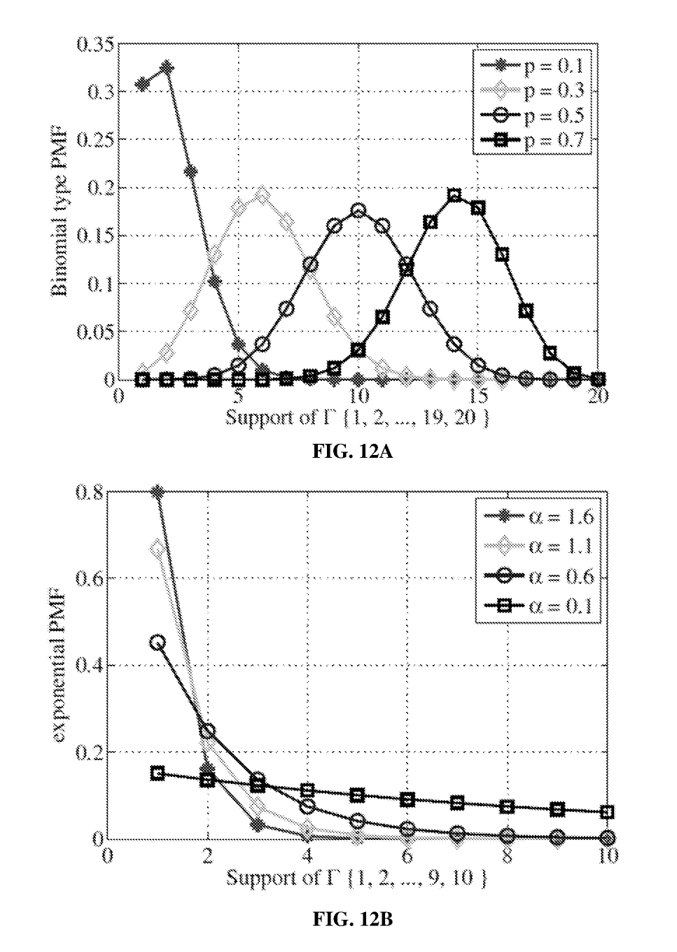

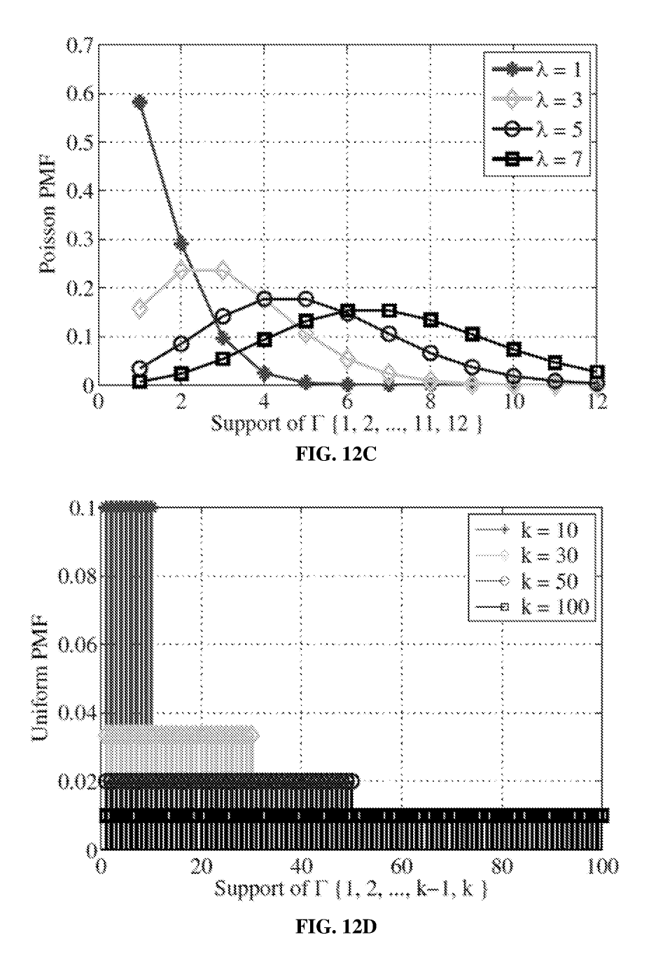

FIGS. 12A, 12B, 12C, and 12D depict plots of the PMFs in Equations 14, 15, 16, and 17 respectively for various parameters. In particular, FIG. 12A depicts plots of the Binomial type PMF in p for k=20, FIG. 12B depicts plots of the Truncated exponential PMF in α for k=10, FIG. 12C depicts plots of the Truncated Poisson PMF in λ for k=12, and FIG. 12D depicts plots of the uniform PMF for different object lengths k. The x-axis of these plots represent the support {1, 2, . . . , k of random variable Γ. These PMFs are chosen to represent a wide range of real-world data update scenarios, in the absence of any standard benchmarking dataset. The truncated exponential PMFs generate thick concentration for lower sparsity levels, yielding best cases for the differential encodings. The uniform distributions illustrate the benefits of the different differential encoding methods for update patterns with no bias on sparse values. The Binomial distributions provide narrow and bell shaped mass functions concentrated around different sparsity levels. The Poisson PMFs model sparse updates spread over the entire support and concentrated around the center.

For a given PMF P_{Γ}(γ), the average storage size for storing the first two versions is E[δ(x₁, x₂)]=n+Σ_{γ=1}^{k}P_{Γ}(γ) min(2γ,k) where n=κk. Similarly, the average number of I/O reads to access the first two versions is E[η(x₁, x₂)]=k+Σ_{γ=1}^{k}P_{Γ}(γ) min(2γ, k). When compared to the non-differential method, the average percentage reduction in the I/O reads and the average percentage reduction in the storage size are respectively computed as

$$\frac{2 k - E [ η ( {x}_{1} , {x}_{2} ) ]}{2 k} 100 and \frac{2 n - E [ δ ( {x}_{1} , {x}_{2} ) ]}{2 n} 100 \qquad ( Equation 18 )$$

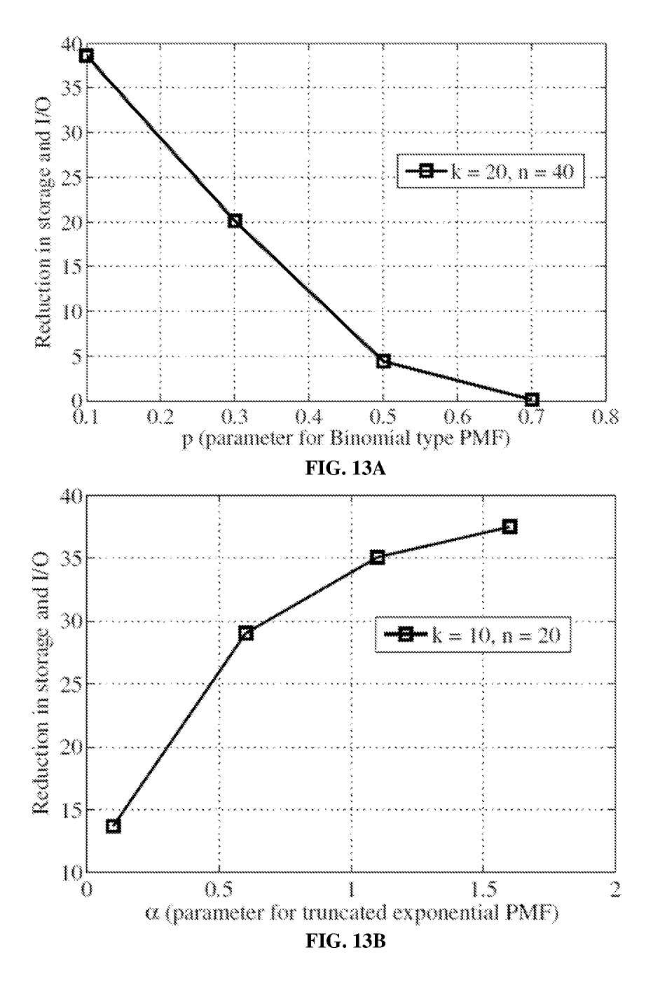

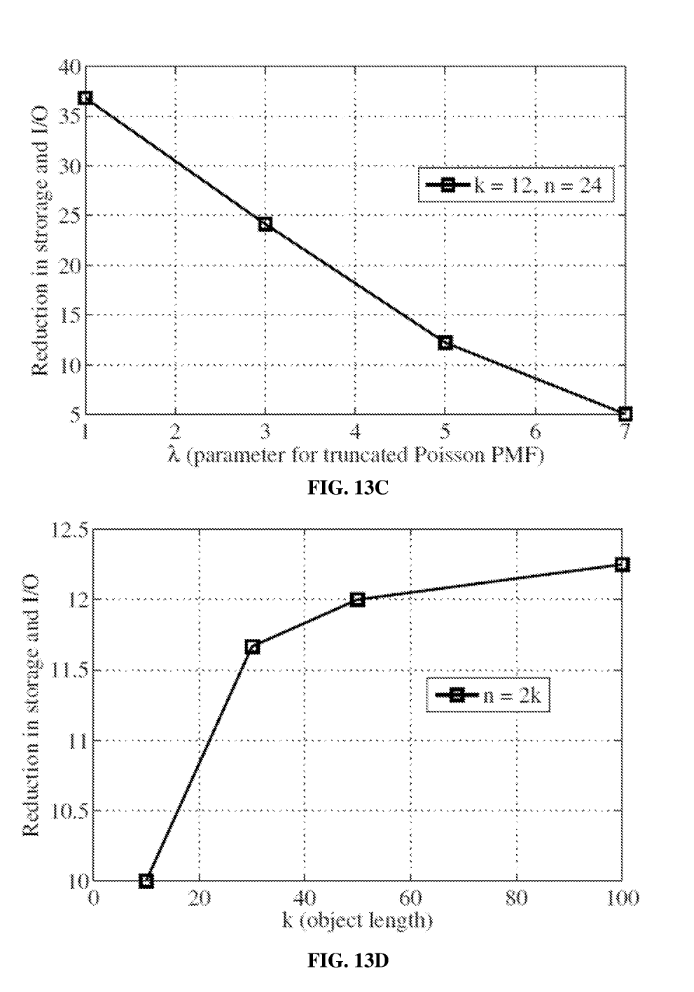

Since δ(x₁, x₂)=κη(x₁, x₂) and κ is a constant, the numbers in Equation 18 are identical. FIGS. 13A, 13B, 13C, and 13D depict plots of the average percentage reduction in the I/O reads and storage size for the PMFs shown in FIGS. 12A, 12B, 12C, and 12D, respectively, when L=2. The plots show a significant reduction in the I/O reads (and the storage size) when the distribution are skewed towards smaller γ. However, the reduction is marginal otherwise. For uniform distribution on Γ, the plot shows that the advantage with the differential technique saturates for large values of k.

Accordingly, how the differential technique reduces the storage space at the cost of increased number of I/O reads have been discussed for the latest version (the 2^{nd} version in the above examples discussed) when compared to the non-differential method. For the basic differential encoding, the average number of I/O reads to retrieve the 2^{nd} version is E[η(x₂)]=E[η(x₁, x₂)]. However, for the optimized encoding, where

$$E [ n ( {x}_{2} ) ] = {\sum }_{γ = 1}^{k} {P}_{Γ} ( γ ) f ( γ ) where f ( γ ) = k + 2 γ when γ < \frac{k}{2} , \\ and f ( γ ) = k ,$$

otherwise.
When compared to the non-differential method, the average percentage increase in the I/O reads for retrieving the 2^{nd} version for the above-described four PMFs for both the basic and the optimized methods are computed. Numbers for

$$\frac{E [ η ( {x}_{2} ) ] - k}{k} 100 , \qquad ( Equation 19 )$$

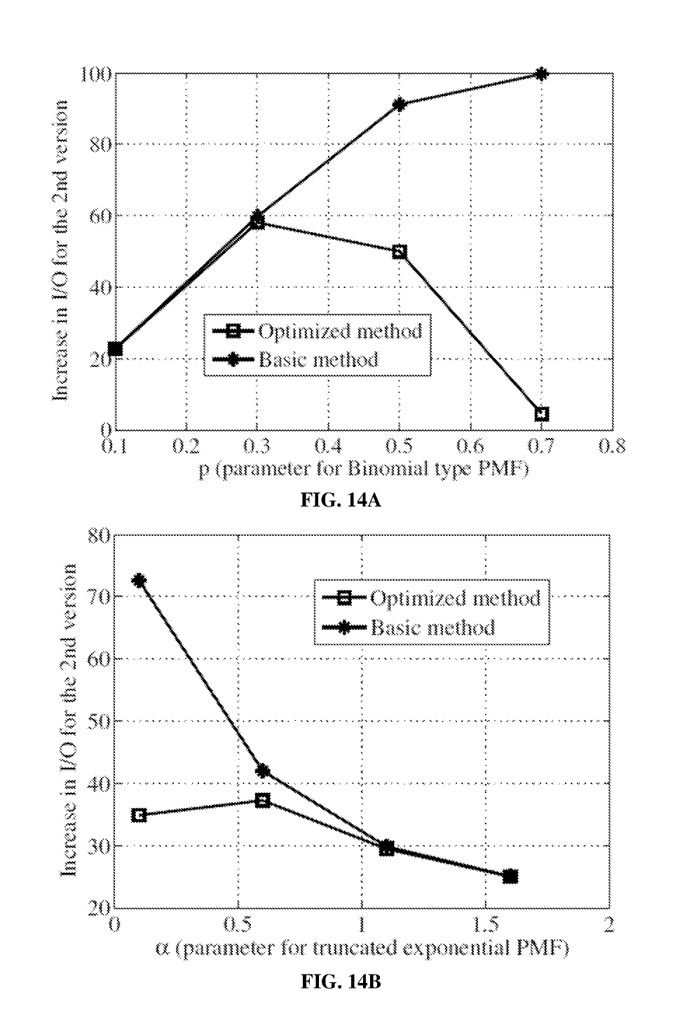

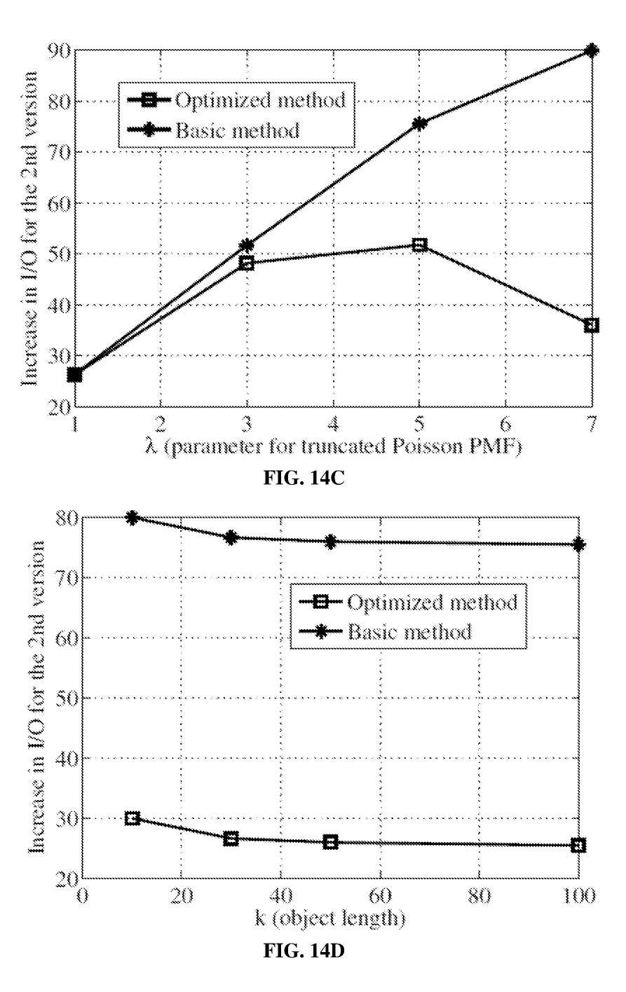

are shown in FIGS. 14A, 14B, 14C, and 14D for the above-described four PMFs, respectively. More specifically, FIGS. 14A, 14B, 14C, and 14D depict plots of the average percentage increase in the I/O reads to retrieve the 2^{nd} version for the above-described four PMFs when L=2. The corresponding values of n and k are the same as that shown in FIGS. 13A, 13B, 13C, and 13D.

### Two-Level DEC: Threshold Design for L=2 Versions

The simulation results to choose the threshold parameter

$$1 \leq T \leq ⌊ \frac{k}{2} ⌋$$

for the two-level DEC technique described hereinbefore will not be presented and discussed. The optimization problem is given in Equation 12 where
E[n(x₁, x₂)]=k+P_{Γ}(γ≦T)2T+P_{Γ}(7>T)k, E[δ(x₁, x₂)]=κE[η(x₁, x₂)]
and 0≦w<1.
   Since E[δ(x₁, x₂)] and E[η(x₁, x₂)] are proportional, solving Equation 12 is equivalent to solving instead

$${T}_{opt} = {argmin}_{1 \leq T \leq ⌊ \frac{k}{2} ⌋} E [ δ ( {x}_{1} , {x}_{2} ) ] , \qquad ( Equation 20 )$$

Table II below list the values of Tₒₚₛ, obtained via exhaustive search over

$$1 \leq T \leq ⌊ \frac{k}{2} ⌋ ,$$

the average number of I/O reads, the average storage size for the optimized two-level DEC method and the

$$\frac{k}{2}$$

level DEC method.

TABLE II
OPTIMAL THRESHOLD VALUE FOR VARIOUS PMFS WITH k = 10

| | | | | |
|---|---|---|---|---|
| Tₒₚₜ | [symbol] [η] (2-level) | [symbol] [δ] (2-level) | [symbol] [η] $( \frac{k}{2} - level )$ | [symbol] [δ] $( \frac{k}{2} - level )$ |

$Binomial \text{:} k = 20 , for \frac{k}{2} - level \text{:} η = 40 and δ = 80$

| | | | | | |
|---|---|---|---|---|---|
| p | | | | | |
| 0.1 | 3 | 28.11 | 56.23 | 24.55 | 49.10 |
| 0.3 | 6 | 35.13 | 70.27 | 31.96 | 63.92 |
| 0.5 | 8 | 38.99 | 77.98 | 38.23 | 76.47 |
| 0.7 | 9 | 39.96 | 79.93 | 39.95 | 79.90 |

$Truncated E xponential \text{:} k = 10 , for \frac{k}{2} - level \text{:} η = 20 and δ = 40$

| | | | | | |
|---|---|---|---|---|---|
| α | | | | | |
| 1.6 | 1 | 13.61 | 27.23 | 12.50 | 25.01 |
| 1.1 | 1 | 14.66 | 29.32 | 12.98 | 25.97 |
| 0.6 | 2 | 15.79 | 31.59 | 14.19 | 28.39 |
| 0.1 | 2 | 18.27 | 36.55 | 17.26 | 34.52 |

$Truncated Poisson \text{:} k = 12 , for \frac{k}{2} - level \text{:} η = 24 and δ = 48$

| | | | | | |
|---|---|---|---|---|---|
| λ | | | | | |
| 1 | 2 | 17.01 | 34.03 | 15.16 | 30.32 |
| 3 | 3 | 20.22 | 40.45 | 18.20 | 36.41 |
| 5 | 4 | 22.24 | 44.49 | 21.06 | 42.13 |
| 7 | 4 | 23.29 | 46.58 | 22.79 | 45.58 |

For simplicity, E[η(x₁, x₂)] and E[δ(x₁, x₂)] are denoted by E[η] and E[δ], respectively, in Table II. To compute the average storage size, κ=2 is used. From Table II, it can be observed that switching to just two levels of compression incurs negligible loss in the I/O reads (or storage size) when compared to the

$$\frac{k}{2}$$

level DEC method. Thus, this demonstrates that the two-level DEC method according to various example embodiments of the present invention is a practical solution to reap the benefits of the differential erasure coding strategy.

When Cauchy matrices are used for Φ_{T}, Equation 12 is solved for both:

$$E [ n ( {x}_{1} , {x}_{2} ) ] = k + {\sum }_{d = 1}^{T} {P}_{Γ} ( γ \leq d ) 2 d + {P}_{Γ} ( γ > T ) k$$

$$E [ δ ( {x}_{1} , {x}_{2} ) ] = n + {P}_{Γ} ( γ \leq T ) 2 T κ + {P}_{Γ} ( γ > T ) k κ$$

Unlike the non-Cauchy case, E[η(x₁, x₂)] and E[δ(x₁, x₂)] are no more proportional and Tₒₚₜ depends on w, 0≦w<1.

To capture the dependency on w, the relation between E[η(x₁, x₂)] and E[δ(x₁, x₂)] was investigated for

$$1 \leq T \leq ⌊ \frac{k}{2} ⌋ .$$

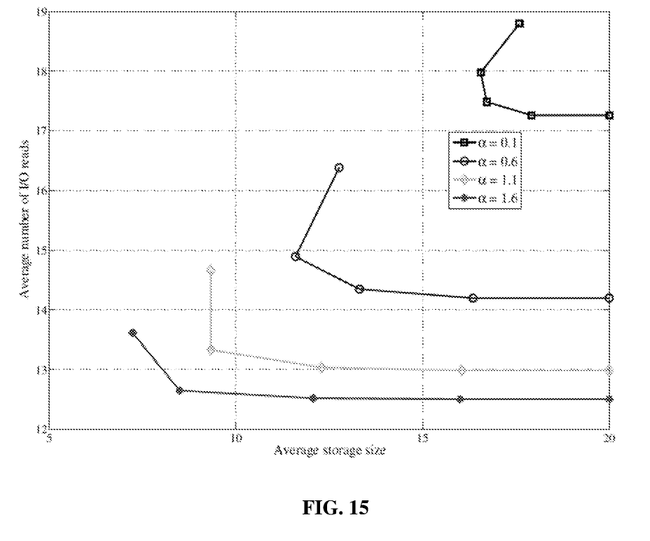

FIG. 15 depicts a plot 1500 of

$$\{ ( E [ δ ( {x}_{1} , {x}_{2} ) ] , E [ δ ( {x}_{1} , {x}_{2} ) ] ) , 1 \leq T \leq \frac{k}{2} \}$$

for the exponential PMFs described hereinbefore. For each curve there are

$$\frac{k}{2} = 5 points corresponding to T ∈ \{ 1 , 2 , … , 5 \}$$

in that sequence from left tip to the right one. The plots indicate the value of Tₒₚₜ(w) for the two extreme values of w, i.e., w=0 and w=1. The curve corresponding to α=0.6 was further investigated. If minimizing E[η(x₁, x₂)] is most important with no constraint on E[δ(x₁, x₂)] (i.e., w=1), then choose

$${T}_{opt} ( 1 ) = \frac{k}{2} .$$

This option results in E[η(x₁, x₂)] which is as low as for the

$$\frac{k}{2}$$

level DEC method described hereinbefore. While if minimizing E[δ(x₁, x₂)] is most important with no constraint on E[η(x₁, x₂)] (i.e., w=0), then Tₒₚₜ(0)=2 results in E[δ(x₁, x₂)] which is the same as for the 2-level DEC method with non-Cauchy matrix as described hereinbefore. For other values of w, the optimal value depends on whether w>0.5. It can be found via exhaustive search over

$$1 \leq T \leq ⌊ \frac{k}{2} ⌋ .$$

Accordingly, it has been demonstrated that using Cauchy matrix for Φ_{T} advantageously reduces the average number of I/O reads to that of the

$$\frac{k}{2}$$

level DEC with just two levels of compression.

### Experimental Results for L>2

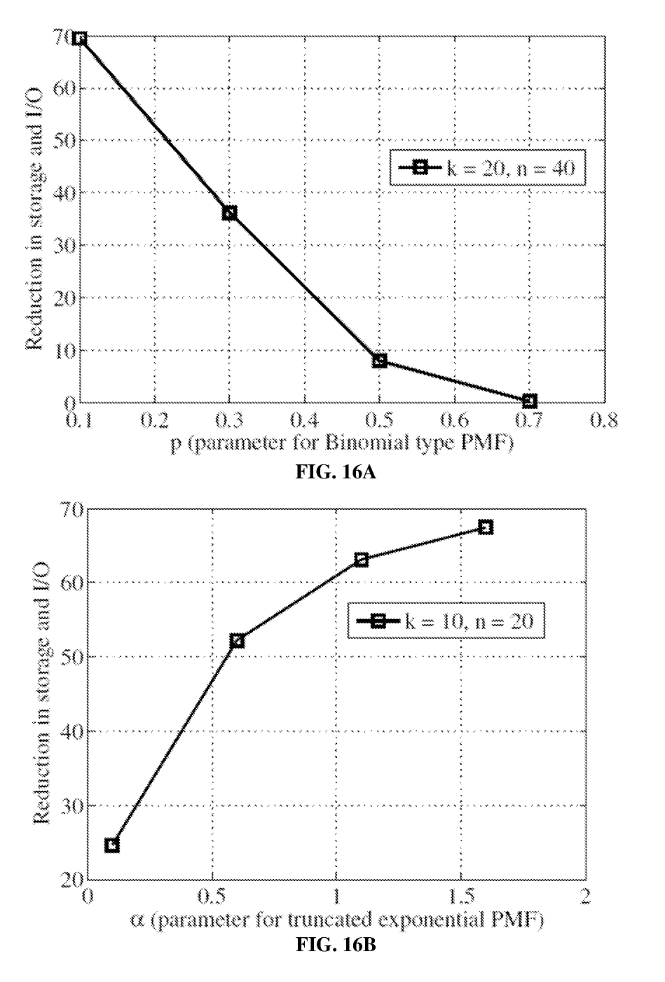

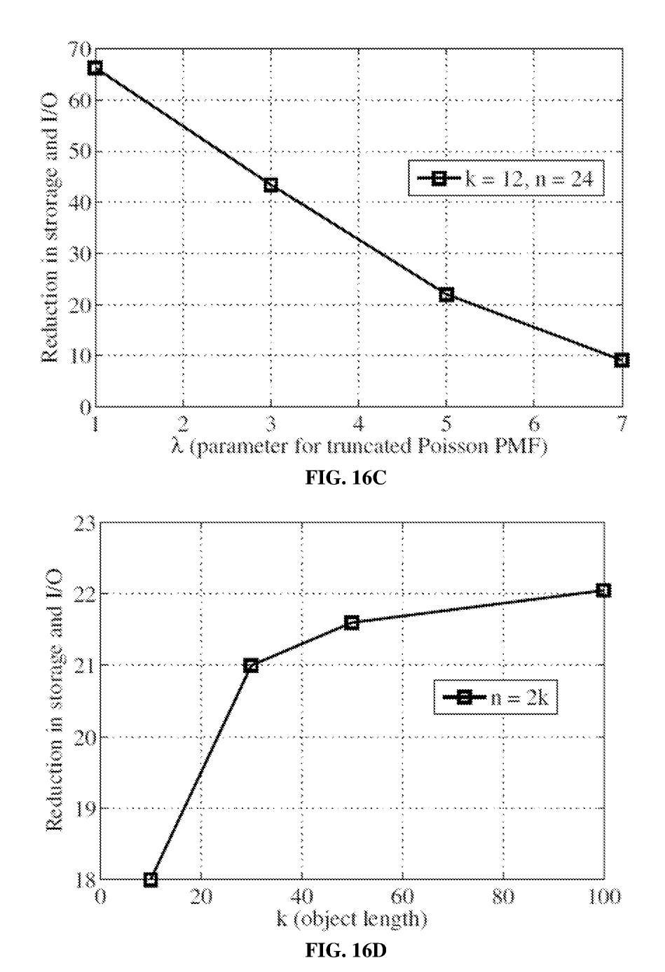

The average reduction in the total storage size for a differential system with L=10 is now presented as an example only for the case where L>2, assuming identical PMFs on the sparsity levels for every version, i.e., P_{Γ}(γⱼ)=P_{Γ}(γ) for each 2≦j<10. The average percentage reduction in the total storage size and total I/O reads number are computed similarly to Equation 18, and are illustrated in FIGS. 16A to 16D. In particular, FIGS. 16A to 16D depict plots 1600, 1610, 1620, 1630 of the average percentage reduction in the I/O reads and total storage size for the four PMFs, respectively, as described hereinbefore when L=10. Identical PMFs are used for the random variable {Γⱼ,2≦j≦10} to obtain the results. The plots show further increase in storage savings compared to the L=2 case described hereinbefore. It will be appreciated that in reality, the PMFs across different versions may be different and possibly correlated. These results are thus only indicative of the saving magnitude for storing many versions differentially.

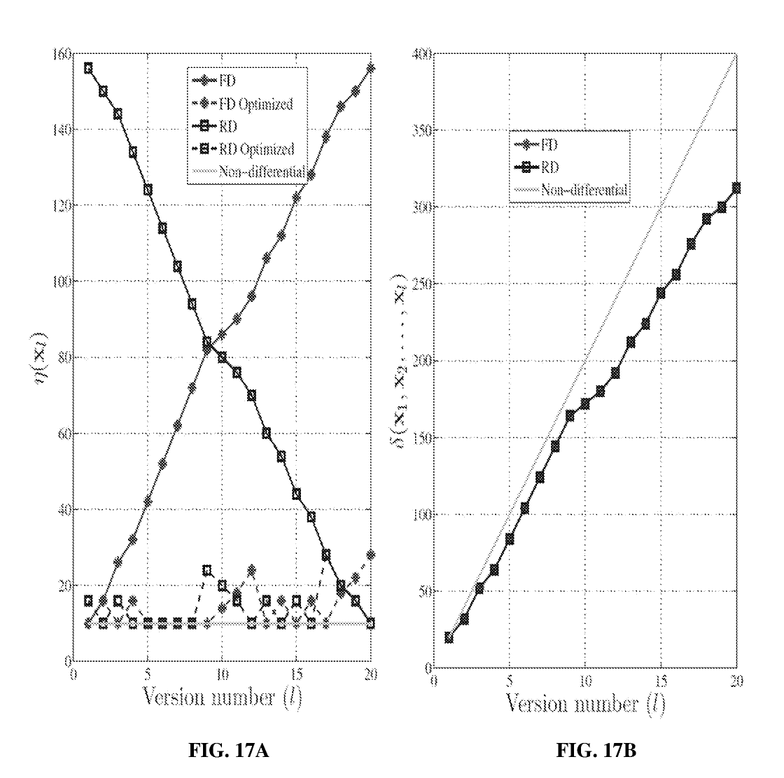

To get better insights for L>2, FIGS. 17A and 17B depict plots 1700, 1710 of the I/O numbers of Examples 3 and 4 described hereinbefore for L=20. In particular, FIGS. 17A and 17B depict plots 1700, 1710 of the I/O and storage for Examples 3 and 4. FIG. 17A shows the number of I/O reads to retrieve only the l-th version for 1≦l≦20, and FIG. 17B provide the shows the total storage size till the l-th version for 1≦l≦20. The results are for forward and reverse differential methods, with basic and optimized encoding. From FIGS. 17A and 17B, it can be observed that more than 20% storage space is saved with respect to the non-differential method, for only slightly higher I/O for the optimized DEC method.

Accordingly, various differential erasure coding techniques have been described hereinbefore according to various embodiments of the present invention for improving storage efficiency and I/O reads while archiving multiple versions of data. The above-described evaluations demonstrate tremendous savings in storage. Moreover, in comparison to a system storing every version individually, the optimized reverse DEC retains the same I/O performance for reading the latest version (which may be most typical), while reducing significantly the I/O overheads when all versions are accessed, in lieu of minor deterioration for fetching specific older versions (which may be an infrequent event).

A method of encoding multiple versions of data involving a data pre-processing technique (which includes method(s) of embedding zero-pads in the original data), will be described below according to various example embodiments of the present invention which probabilistically increases the chance that the nature of difference across consecutive versions of data, when represented in binary format, actually has the kind of sparsity which the method can exploit in practice to yield the storage savings. This advantageously promotes sparsity between versions of data object and enables the method to handle changes in the size/length of the file contents in the data object between versions of the data object. In this regard, addition of zeropads itself adds storage overheads so various example embodiments of the present invention determine the quantum and placement of zero-pads where the cumulative effect is net gains in storage overheads. In addition, a differential versioning based data storage (DiVers) architecture for distributed storage systems will also be described later below according to various example embodiments of the present invention, which relies on the different erasure coding techniques described herein that exploits sparsity across versions.

Various embodiments of the present invention address the encoding of mutable content. In this regard, the design of erasure codes may assume fixed sized data objects, to be divided into fixed sized blocks of data. Furthermore, even if a single bit in one of the blocks changes, the coding sematic may treat it as a distinct block. Consequently, even a minor change near the start of a file may ripple across all the blocks at the coding granularity. To ameliorate this situation, according to various embodiments of the present invention, the method may be modified with zero padding techniques, taking into account insertions, deletions and in-place alterations. To reap the benefits of zero padding techniques in terms of storage gain, according to various embodiments of the present invention, they are combined with the differential encoding techniques described herein which deal with different sized (compressed) information, and a data placement strategy. The storage gains are then validated later, where the quantum and placement of zero pads are explored and show via experiments (with a wide range of workloads) a 20-70% reduction in storage size against alternative baselines can be achieved. Thereafter, two preferred aspects of the DiVers architecture will be discussed. Since difference among consecutive versions, rather than full copy of a new version of data are encoded and stored in a dispersed manner, and additionally, because of the introduction of zero-paddings, access of relevant data has to be supported by appropriate meta-information, the associated data structure will be described according to various example embodiments of the present invention. Furthermore, an example protocol that dictates the interaction among storage nodes for an application client to read any version of data differentially encoded, and that orchestrates the creation of a new version will be described later. It will be appreciated by a person skilled in the art that many system aspects described hereinafter, in particular that of handling variable length objects, are not limited to differential erasure encoding (which may also be referred to as sparsity exploiting coding (SEC)).

### Baseline Architecture

Considering an architecture akin to GFS which comprises a master, client nodes accessing data, and a set of chunk servers. While the master harbours the metadata of the file system, the chunk servers preserve the data object. Henceforth, in various example embodiments of the present invention, a single client model is considered to create globally serialized order of changes and the nuances of how multiple clients may need to secure locks from the master server are excluded for simplicity and clarity. It will be appreciated that existing approaches used in GFS may be adapted directly in the distributed storage system disclosed herein. It will also be appreciated that the architecture of the file-system in GFS may change over time, but such changes will not have any bearing on the discussed herein. Typically, to write a new object, the client garners the file handle from the master, and then directly contacts a chunk server to store the object. The system further distributes the object into fixed size smaller objects which may be referred to as chunks, which are replicated, or erasure encoded, across (for instance, for replication, three) chunk servers for resilience against failures. To update a stored data object, the physical address of a chunk server (that hosts the chunks) is forwarded to the client by the master, using which the client reads, edits and then stores the object back on the same server. For the updated version, the system once again divides the new object into fixed size chunks and stores them. In order to update the modifications to the other chunk servers (which maintain redundancy), the use of a benchmark delta encoding system is assumed and henceforth referred to as selective encoding (SE), where only the modified chunks between the two versions are transferred to the other chunk servers, thereby reducing the communication bandwidth. This method is effective if the updated version retains its size, and has few modifications. However, if the object size changes due to insertions or deletions, or when changes propagate at bit level, then dividing the updated version into fixed size chunks need not result in sparsity in the difference object across versions. However, since the SEC framework enjoys savings in I/O and storage based on sparsity, various embodiments of the present invention address the issues of ripple effects from updates, and encoding variable length objects. The above architecture will be used as a baseline to show the advantages of the example architecture, DiVers, which handles these practical problems by introducing specifically placed zero-pads to induce sparsity between versions.

### Divers: System Architecture for SEC

An example system architecture, DiVers, that supports the storage of erasure coded deltas (difference vector or difference object) based on SEC will now be described according to example embodiments of the present invention. In this architecture, a blob (binary large object) is broken down into chunks of fixed size, which are then stored across clusters of chunk servers. The system also maintains metadata which typically contains the list of file names, mapping from file name to chunk indices, and from chunk indices to chunk servers along with their physical addresses. When a client requests for a file in the blob, the master server returns the file handle along with the addresses of the nearest chunk servers containing the chunks. The details of how the data structure encapsulates the system meta information will be described later below under Data Structures for Meta-Information Encapsulation in DiVers, while a protocol to orchestrate the cluster interactions between application client(s), master and chunk servers will also be described later below under Cluster Management and Protocols, according to various example embodiments of the present invention. Various example embodiments of the present invention will now be described on modifying the method of encoding multiple versions of data to handle files of arbitrary and changing sizes, yet promoting sparsity.

Step 1:

Let [symbol] ₁ be the first version of a file of size V units to be saved to DiVers. The system distributes the file contents into several chunks, each of size Δ units. Within each chunk, δ units of zero pads are allocated at the end while the rest of it are dedicated for the file content. Thus, the V units of the file are spread across

$$M = ⌈ \frac{V}{Δ - δ} ⌉ \qquad ( Equation 21 )$$

chunks {C₁, C₂, . . . , C_{M}}, where ┌•┐ denotes the ceiling operator. The zero pads are particularly added at the end of every chunk to promote sparsity in the difference between two successive versions.

Example 7: Let V=10000, Δ=500, and δ=20 units. Applying Equation (3), the file is divided into M=21 chunks where the file content part of the first 20 chunks {C₁, C₂, . . . , C₂₀} are completely filled whereas only the first 400 units are filled in C₂₁ (out of the allocated 480 units). As a result, C₂₁ has a total of 100 units of zero pads, 80 corresponds to unfilled space from the file and 20 from the standard zero pads.

Once the file contents are divided into M chunks, these chunks are appropriately stored across different chunk servers, using an (n, k) erasure code: the code is applied on a block of k data chunks to output n (>k) chunks which includes the data chunks and additional n−k encoded chunks that are generated to provide fault tolerance against potential failures. The parameter k is the design choice to be optimized for the architecture with respect to M. Since M is file dependent, there can be two possible relations between M and k:

Case 1:

When M<k, additional M−k chunks containing zeros are appended to create a block of k chunks. Henceforth, these additional chunks are referred to as zero chunks. Then, the k chunks are encoded using an (n, k) erasure code.

Case 2:

When M≧k, the M chunks are divided into

$$G = ⌈ \frac{M}{k} ⌉$$

groups G₁, G₂, . . . , G_{G}. The last group G_{G} if found short of k chunks is appended with zero-chunks. The k chunks in each group are encoded using an (n, k) erasure code. Finally, these n chunks are stored across n independent chunk servers in the backend.

### Example 8

For the parameters in Example 7, if k=8, then we have G=3 where G₁={C₁, C₂, . . . , C₈}, G₂={C₉, C₁₀, . . . , C₁₆}, and G₃={C₁₇, C₁₈, . . . , C₂₄}. For G₃, the chunks C₂₂, C₂₃, C₂₄ are the zero-chunks. A (12, 8) erasure code is chosen to encode the chunks within each group, which results in a total of 36 chunks after encoding.

For the first version [symbol] ᵢ, the G groups of chunks together have δM+NΔ units of zero pads, where 1≦N<k, represents the number of zero-chunks added to make G_{G} contain k chunks. In addition, the M-th chunk may have extra padding due to the rounding operation in Equation 21. Note that δM units of zero pads (that are distributed across the chunks) shield propagation of changes across chunks when an insertion is made in subsequent versions of the file. Thus, this object can now withstand a total of δM units of insertion (anywhere in the file if δM<NΔ) by retaining G groups for the second version. The advantages of zero pads by explaining the process of storing the (j+1)-th version [symbol] ⱼ₊₁ of the file, j≧1, will now be described below.

Step j+1, for j≧1: To generate the (j+1)-th version, it is assumed that the client changes the file through insertion of new content to the existing file, deletion of some existing content, and modification of the existing content. These operations potentially change the size of the file contents in some chunks.

### Handling Insertions

For the (j+1)-th version, the system identifies the difference in the size of the file contents in every chunk. Then the changes in the file contents are carefully updated in the chunks, in the increasing order of the indices 1, 2, . . . , M, so as to minimize the number of chunks modified due to changes in one chunk. For some 1≦i<M, if the contents of Cᵢ grow in size by at most δ units, then some zero pads are appropriately flushed out to make space for the expansion. This Cᵢ will have fewer zero pads than the first version. On the other hand, if the contents of Cᵢ grow in size by more than δ units, then the first Δ units of the file content are written to Cᵢ while the remaining units are shifted to Cᵢ₊₁. As a result, the existing contents of Cᵢ₊₁ are in turn shifted, and hence, it will have fewer zero pads than S. In this process, the propagation of changes in the chunks continues until all the changes in the file are reflected.

### Example 9

(to illustrate an advantage of zero pads) Consider the parameters in Examples 7 and 8. For the second version, let the contents of C₁ grow in size to contain 490 units (10 units in addition to the first version). Since C₁ has 20 units of zero pads, the 490 units of file content are filled within the chunk while flushing out 10 zero pads. Hence C₁ contains 10 units of zero pads, to absorb the changes for the next version. Since the insertions are fewer than 6, only the first chunk is modified whereas the second chunk is left undisturbed.

### Example 10

(to illustrate propagation of changes across chunks) For the third version, let the file contents of C₁ grow in size to 510 units. The first 500 units are filled within C₁ by flushing out all zero pads, whereas the remaining 10 units are forwarded to C₂. The existing contents of C₂ are then pushed right by flushing out its 10 units of zero pads. If no changes are made to C₂, then it will have 10 zero pads at the end. Finally, if there are no changes made to the remaining chunks of the first group, the number of modified chunks is just two.

### Handling Deletions

The idea of placing zero pads is primarily to arrest propagation of changes across chunks due to insertion of new contents. On the other hand, when some file contents are deleted, the zero pads continue to block propagation, however this time in the reverse direction. Since deletion results in reduced size of the file contents in chunks, this is equivalent to having additional zero pads (of the same size as that of the deleted patch) in the chunks along with the existing zero pads. After this process, the metadata should reflect the total size of the file contents (potentially less than Δ−δ) in the modified chunk. Thus, deletion of file contents boosts the capacity of the data structure to shield larger insertions in the next versions.

### Example 11

(to showcase deletion of file contents) For the fourth version, let the file contents in C3 reduce in size to 420 units due to deletion of some file contents. In addition to the existing δ=20 zero pads, the deleted file contents also contribute 60 more to make it 80 units of zero pads in total.

### Encoding Difference Objects

Example 10 illustrated the need for shifting the file contents across the chunks when the insertion size is more than δ units. Going further, if the insertion size is large enough, then new chunks (or even new groups) have to be added to the existing chunks (or groups), thus changing the object size of the (j+1)-th version. Note that the differential encoding strategy requires two successive versions to have the same object size to compute the difference. In particular, the reverse DEC described hereinbefore was adopted whereby the latest version of the object is stored in full while the preceding versions are stored in a differential manner. Once the contents of the (j+1)-th version is updated to the chunks, the difference between the chunks of the j-th and the (j+1)-th version is computed. Then a difference chunk is declared to be non-zero if it contains at least one non-zero element. Within a group, if the number of non-zero chunks, say γ of them, is smaller than

$$\frac{k}{2}$$

then the difference object is compressed to contain 2γ chunks. This procedure of storing the difference objects is continued until the modified object size is at most kG chunks.

Since the whole object is distributed across chunk servers, rather than in one place, an example method to compute the difference object and then to compress it will be described later according to various example embodiments of the present invention. Details on how to encode and store these difference objects will be presented later according to example embodiments of the present invention.

### Definition 2

A set of consecutive versions of the file that maintains the same number of groups is referred to as a batch of versions, while the number of such versions within the batch is referred to as the depth of the batch. The case when insertions change the group size is addressed next as a source for resetting the differential encoding strategy.

Criteria to Reset SEC

Criterion 1:

Starting from the second version, the process of storing the difference objects continues until G remains constant. When the changes require more than G groups, i.e., the updates require more than kG chunks, the system terminates the current batch, and then stores the object in full by redistributing the file contents into a new set of chunks. To illustrate this, let the j-th version of the file (for some j>1) be distributed across Mⱼ chunks, where

$$⌈ \frac{{M}_{j}}{k} ⌉ \leq G .$$

Now, let the changes made to the (j+1)-th version occupy Mⱼ₊₁ chunks where

$$⌈ \frac{{M}_{j}}{k} ⌉ \leq G .$$

At this juncture, the file contents are reorganized across several chunks with δ units for zero pads (as done for the first version). After re-initialization, this file has

$${G}^{′} = ⌈ \frac{{M}_{j + 1}}{k} ⌉$$

groups.

Criterion 2:

Another criterion to reset is when the number of non-zero chunks is at least

$$\frac{k}{2}$$

within every group. Due to insufficient sparsity in each group, there would be no saving in storage size in this case, and as a result, a new batch has to be started. However, a key difference from criterion 1 is that the contents of the chunks are not reorganized since the group size has not changed.

### Example 12

(illustrating Criterion 1) Continuing from Example 11, in the fourth version C₁ is completely filled (with no zero pads), C₂ has 10 units of zero pads, C₃ has 80 zero pads, whereas chunks C₄, C₅, . . . , C₂₄ together have 1940 zero pads. For the fifth version, say 2000 units are inserted into the chunk C₁₆. As a result, the zero pads of C₁₆, C₁₇, . . . , C₂₄ must absorb the insertions in C₁₆. However, these chunks have a total of only 1700 units of zero pads. Hence, after suitable shifting of data, chunks C₁₆, C₁₇, . . . , C₂₄ get completely filled, while the excess 300 units of data is placed in a new chunk say, C₂₅. With this overflow criterion, the differential strategy is reset since G is 4. Equation 20 is then applied to redistribute the total data of 11970 units (10000 from first version, 10 more from second, 20 more from third, 60 deleted from fourth, 2000 more from the fourth version) into 25 chunks. With k=8, we have G=4 where the 4-th group is appended with 7 zero-chunks. Finally, these 4 groups of chunks are encoded using a (12, 8) erasure code. A snapshot of the parameters at different versions of the Examples 7 to 12 are presented in Table III below.

TABLE III
SNAPSHOT OF THE UPDATES AT THE END OF l-TH
VERSION FOR 1 ≦ l ≦ 5 IN EXAMPLES
7-12 WITH PARAMETERS Δ = 500, δ = 200 AND k = 8.

| Version | | | | Number | |
|---|---|---|---|---|---|
| number | | Object | | of | |
| l | Objects | size | G | Batches | Modified chunks |
| 1 | {x₁} | 10000 | 3 | 1 | {C₁, C₂, . . . , C₂₁} |
| 1 | {z₂, x₂} | 100010 | 3 | 1 | {C₁} |
| 3 | {z₂, z₃, x₃} | 10030 | 3 | 1 | {C₁, C₂} |
| 4 | {z₂, Z₃, z₄, x₄} | 9970 | 3 | 1 | {C₃} |
| 5 | {z₂, z₃, z₄, x₄, | 11970 | 4 | 2 | {C₁₆, C₁₇, . . . , C₂₅} |
| | x₅} | | | | |

### Erasure Encoding Methods for Sparse Objects

To encode a full version of a data object, an erasure code is applied on a batch of k chunks, each of size Δ units, namely, an (n, k) erasure code is applied on symbols of fixed size Δ units. However, to encode the difference object, the choice of the erasure code parameters depends on the number of modified chunks and the choice of the symbol size. Two methods of storing the non-zero (or the modified) chunks will now be described according to various example embodiments of the present invention:

A method for DiVers:

if there are

$$γ ( < \frac{k}{2} )$$

non-zero chunks in the difference object, then the k chunks are appropriately compressed to 2γ chunks. Otherwise, the k chunks of the difference object are encoded in full.

A Method Applicable for the Selective Encoding Architecture:

only the modified chunks (irrespective of their number relative to k) are stored by keeping track of their indices in the metadata.

For the DiVers method, since the difference object is compressed using a suitable measurement matrix, there is no need to store the indices of the non-zero chunks, for reconstruction. However, for the selective encoding method, the modified chunks are stored in a separate storage space while their indices are preserved in the metadata, for reconstruction.

For both methods, the number of non-zero chunks is variable and depends on the sparsity level of the differences. If the symbol size is fixed to Δ bytes, then this demands erasure codes of different dimensions for different sparsity levels. In practice, handling multiple erasure codes may not be viable, especially when k is moderately large. Hence, according to various example embodiments of the present invention, a method to encode these objects using a single erasure code is provided, by keeping k fixed but changing the symbol size of the code depending on the sparsity level. The encoding of k chunks within one group will now be described, although it will be appreciated that the method can be applied in parallel to encode chunks in other groups.

### Encoding Method for DiVers

As described hereinbefore in relation to the differential encoding method according to various example embodiments, let the sparsity of the difference object between two successive versions j and j+1 be

$$γ < \frac{k}{2} .$$

This difference object can be viewed as a k-length vector zⱼ₊₁ which is γ-sparse over symbols of size Δ units. Applying the compressed sensing technique as described hereinbefore, zⱼ₊₁ can be compressed using a suitable 2γ×k matrix Φ_{γ} over symbols of Δ units, to obtain a new vector of length 2γ symbols given by zⱼ₊₁′=Φ_{γ}zⱼ₊₁. How to store the 2 compressed chunks using a single (n, k) erasure code that should work for

$$1 \leq γ \leq \frac{k}{2}$$

will now be described according to various example embodiments of the present invention.

A preferred strategy is to divide the compressed object (of size 2γΔ units) into k blocks each of size

$$\frac{2 γ Δ}{k} ,$$

i.e., the compressed object is viewed as a k-length vector over symbols of size

$$\frac{2 γ Δ}{k}$$

units. Considering the minimum value of γ=1, an (n, k) erasure code is designed whose n×k generator matrix G (see Equation 1) is over symbols of size

$$η = \frac{2 Δ}{k} .$$

If one unit corresponds to one bit, then q=2. Then this generator matrix is appropriately replicated (as in Definition 3 below) to encode the compressed objects of size 2γΔ units for any 1≦γ≦k/2. The parameters Δ and k are chosen such that k divides Δ.

### Definition 3

Let BεF_{q}_{^{m}}^{n×k}, \tilde{B}ᵣεF_{q}_{^{rm}}^{n×k} given by:

$$B = [ \begin{matrix}{b}_{1 , 1} & … & {b}_{1 , k} \\ ⋮ & ⋮ & ⋮ \\ {b}_{n , 1} & … & {b}_{n , k}\end{matrix} ] , \\ {\tilde{B}}_{r} = [ \begin{matrix}{\tilde{b}}_{1 , 1} & … & {\tilde{b}}_{1 , k} \\ ⋮ & ⋮ & ⋮ \\ {\tilde{b}}_{n , 1} & … & {\tilde{b}}_{n , k}\end{matrix} ] ,$$

where B has coefficients in F_{q}_{^{m}}, m≧1 and q≧2, while B̅ᵣ is the r-augmented matrix of B with coefficients F_{q}_{^{rm}}^{n×k}, r≧1, where b̅_{i,j}=[b_{i,j} b_{i,j} . . . b_{i,j}] is viewed as a symbol in F_{q}_{^{rm}} by juxtaposing b_{i,j}, r times, ∀i,j.

Encoding Procedure:

For the absolute version (which is of size kA units), first the object xⱼ₊₁ is viewed as an element in F_{q}_{^{Δ}}^{k}. Then, the generator matrix of the erasure code is chosen to be the

$$\frac{k}{2}$$

augmented matrix of G, i.e.,

$${\tilde{G}}_{\frac{k}{2}} ∈ {F}_{{2}^{Δ}}^{n \times k} .$$

Then the codeword cεF_{q}_{^{Δ}}ⁿ is obtained as:

$$c = {\tilde{G}}_{\frac{k}{2}} {x}_{j + 1} ,$$

where the arithmetic operation is over the finite field F_{q}_{ⁿ}; any two symbols a, bεF_{q}_{^{Δ}} are viewed as

$$\frac{k}{2}$$

length vectors over F_{q}_{ⁿ} as

$$a = [ {a}_{1} , {a}_{1} , … , {a}_{\frac{k}{2}} ] and b = [ {b}_{1} , {b}_{1} , … , {b}_{\frac{k}{2}} ] ,$$

and the arithmetic operations between a and b are defined component-wise over the base field F_{q}_{^{η}}.

For the difference object if the compressed object zⱼ₊₁′ is of size 2γΔ units, for some

$$1 \leq γ < \frac{k}{2} ,$$

then it is viewed as a k-length vector over symbols of size πη units. For this object size, the generator matrix of the erasure code is chosen to be the γ-augmented matrix of G, i.e., \tilde{G}γεF_{q}_{^{lη}}ⁿ. Then the codeword cεF_{q}_{^{Δ}}ⁿ is obtained as:

c=\tilde{G}_{γ}zⱼ₊₁′,

where the arithmetic operation is over the finite field F_{q}_{^{η}}. Similar to encoding an absolute version two symbols

$$a , b ∈ {F}_{{q}^{\frac{2 γ Δ}{{ }^{k}}}}$$

are viewed as γ-length vectors over F_{q}_{^{η}} as a=[a₁, a₁, . . . , a_{γ}] and b=[b₁, b₁, . . . , b_{γ}]. Further, the addition and multiplication operations between a and b are defined component-wise over the base field F_{q}_{^{η}}. Note that the finite field operations are fixed over F_{q}_{^{η}} irrespective of the sparsity of the object. However, the only dependency on the sparsity is the construction method of the corresponding generator matrix, and the segmentation for finite field arithmetic. From the implementation viewpoint k must be an even number. The above encoding method will now be illustrated in the following example.

### Example 13

Let n=12, k=8, Δ=500 and γ=2. For these parameters, the compressed object is of size 2γΔ=2000 units. This object is divided into k=8 blocks each of size

$$\frac{2 l Δ}{k} = 250 units .$$

Considering γ=1, generator matrix G of the basic (12, 8) erasure code is designed over symbols of size 125 units. To encode the difference object, the generator matrix is chosen to be the 2-augmented matrix of G. Overall, the total storage size after erasure coding is 3000 units.

### Encoding Method for Selective Encoding

Similarly, let γ be the number of modified chunks for the (j+1)-th version. Unlike the technique for DiVers, γ can take any number within k. First, the indices of the non-zero chunks are stored in metadata. Then, the non-zero chunks of size γΔ units are gathered together for erasure coding. A preferred strategy is to divide the nonzero chunks (of size γΔ units) into k blocks each of size

$$\frac{γ Δ}{k} ,$$

i.e., the modified chunks is viewed as a k-length vector yⱼ₊₁ over symbols of size

$$\frac{γ Δ}{k}$$

units. Considering the minimum value of γ=1, an (n, k) erasure code is chosen whose n×k generator matrix G is over symbols of size

$$β = \frac{Δ}{k} , i . e . , G ∈ {F}_{{2}^{β}}^{n \times k} .$$

From here on, the encoding procedure is similar to that for DiVers, except that, to encode the object of size γδ units, the generator matrix to be the γ-augmented matrix of G, i.e.,

$${\tilde{G}}_{γ} ∈ {F}_{{q}^{\frac{γ Δ}{k}}}^{n} .$$

On similar lines, the finite field operations are over the field

$${F}_{{q}^{\frac{Δ}{k}}} .$$

To summarize, the key differences between the two methods are listed in Table IV below. A comparison between the two methods for different synthetic workloads will be discussed later.

TABLE IV
Key Differences Between Storing the Objects with SEC and Selective
Encoding

| Parameter | SEC | Selective Encoding |
|---|---|---|
| Zero pads | Inserted at the end of every | Not inserted in chunks, |
| | chunk. If needed additional | however, inserted at the |
| | zero pads inserted at the end | end to get multiple of k |
| | to get multiple of k chunks. | chunks for erasure coding |
| Dependency on sparisty level | $Applicable when 1 \leq l < \frac{k}{2}$ | Applicable for any 1 ≦ l ≦ k |
| Metadata | Sparsity level and | Sparsity level and indices |
| | measurement matrix | of the non-zero chunks |
| Symbol size of the erasure code | $\frac{2 Δ}{k}$ | $\frac{Δ}{k}$ |
| Storage size | High | Low |
| savings | | |

### Allocation Strategy: Fault Tolerance and I/O

Having chosen a (n, k) erasure code, the n encoded blocks of the object have to be distributed across n servers from the existing pool of chunk servers in order to realize best fault tolerance. Although the number n is fixed, the size of each block depends on (i) whether the object is from the difference between two consecutive versions or the absolute version of the file (if it is absolute then one block of object corresponds to one chunk, otherwise, the size of one block is less than that of one chunk), and (ii) the sparsity of the difference object within every group. In this context, the term blocks is used to distinguish them from fixed A-sized chunks.

### Example 14

From Example 13, to encode the absolute version, size of one block is 500 units. However, for the difference object when γ=2, size of one block is 250 units. Techniques/methods of allocating encoded blocks when the system has abundant chunk servers will be described below according to various example embodiments of the present invention, otherwise, the default allocation strategy may be to place all the versions on one cluster of n chunk servers. Since the encoded blocks from the difference objects are static and small in size, these blocks may be placed within some chunks, and in parallel, the metadata may be updated with the chunk indices along with the start and end positions. Storing different versions of the file across a single cluster of n servers drawbacks:

Fault Tolerance:

Assuming the (n, k) erasure code can withstand any dₘᵢₙ disk failures, loss of dₘᵢₙ+1 or more disks leads to loss of all the versions, including those coming from different batches.

I/O Efficiency:

Since different versions are residing in the same chunk servers, the chunks have to be accessed sequentially, thereby increasing the latency.

The above drawbacks give scope for better placement strategies when sufficiently large number of chunk servers are available. The placement strategies addressing whether to store the encoded blocks (across different versions and different batches) in a distributed or colocated manner will now be discussed.

Placement of Encoded Blocks within a Batch

Different versions within one batch are correlated due to the differential strategy, therefore, losing one (especially the latest one) is equivalent to losing several (or all the) versions within a batch. Hence, storing these correlated versions across different clusters of n servers does not increase fault tolerance. Indeed, let d be the depth (see Definition 2) of a batch where the first d−1 versions are differentially encoded, whereas the d-th version (the latest version) is absolutely encoded. By placing these d correlated versions across d mutually exclusive clusters (each containing n chunk servers) so that the failure events of nodes are statistically independent, the probability of availing all the versions, i.e., not losing any version, is (1−p)^{d}, where p is the probability of losing dₘᵢₙ+1 or more servers within a cluster of n servers. On the other hand, by placing these d versions across a single cluster of n servers, the probability of availability of all the versions is 1−p, which is greater than the distributed allocation. Thus, different versions within one batch should be allocated on a single cluster of chunks servers. While there is no gain in fault tolerance by placing the versions within a batch distributively, this could be beneficial from an I/O access point of view, as different versions within the batch can be read in parallel.

### Placement of Chunks Across Batches

As described hereinbefore, resetting the SEC strategy results in several batches of versions that are mutually uncorrelated (see Definition 2). As above, the versions in a batch are stored across one cluster of n servers. However, whether to store these batches on the same cluster will now be discussed according to various example embodiments of the present invention. If v batches are stored across v cluster of servers, then the probability of availing at least one batch of versions is 1−p^{v}. By placing them on the same cluster of n servers the probability of availing at least one batch is 1−p, which is smaller distributed allocation. Thus, placing different batches across mutually non-intersecting clusters increases the chances of recovering some versions of the file in the event of nodes' failure. In addition, this allocation improves I/O performance, since these versions can be accessed in parallel. Thus, according to various example embodiments of the present invention, distributed placement for different batches of versions are selected, if there are adequate number of chunk servers. Based on the structure of zero pads, the principles of object placements, and the experiment results (which will be described next), example protocol for interactions and the related metadata management for the DiVers architecture will be described later under Data Structures for Meta-Information Encapsulation in DiVers and Cluster Management and Protocols.

### Experiment Results

Experiments were conducted with several synthetic workloads, capturing wide spectrum of realistic loads to demonstrate the efficacy of the DiVers architecture. The main points are (1) to illustrate the advantage of the DiVers architecture against the baseline architecture discussed hereinbefore, as well as another naive baseline architecture where each version is fully coded and treated as distinct objects, and (2) to determine the right strategy to place the zero pads (with emphasis on its position and size) in order to promote sufficient sparsity in the difference object for different classes of workloads. Throughout the experiments and unless stated otherwise, the reverse differential method is used where the order of storing the difference vectors is reversed as {z₂, z₃ . . . , z_{L}, x_{L}} for both the baseline and the DiVers architecture, as it facilitates direct access to the latest version of the object.

Comparison with the Baseline Architecture

A yardstick for comparison is the baseline architecture that uses concepts from selective encoding as discussed hereinbefore to store the modified chunks. The storage savings of the selective encoding method are quantified and compared with that of DiVers'. For the selective encoding method, although there are no pre-allocated zero pads, they indirectly appear at the end to generate k (or its multiple) number of chunks. In terms of metadata, the selective encoding method needs to store the indices of the modified chunks, but SEC needs not. However, for making SEC practicable, more sophisticated data structure (discussed later under Data Structures for Meta-Information Encapsulation in DiVers) may be required, in order to keep track of the more intricate manner of zero-padding advocated in the DiVers architecture. For the rest of the discussions of experimental results, by SEC, we refer to the enhancements in the coding strategy itself, as well as processing of the raw-data with the intricate zero-padding mechanisms introduced in DiVers.

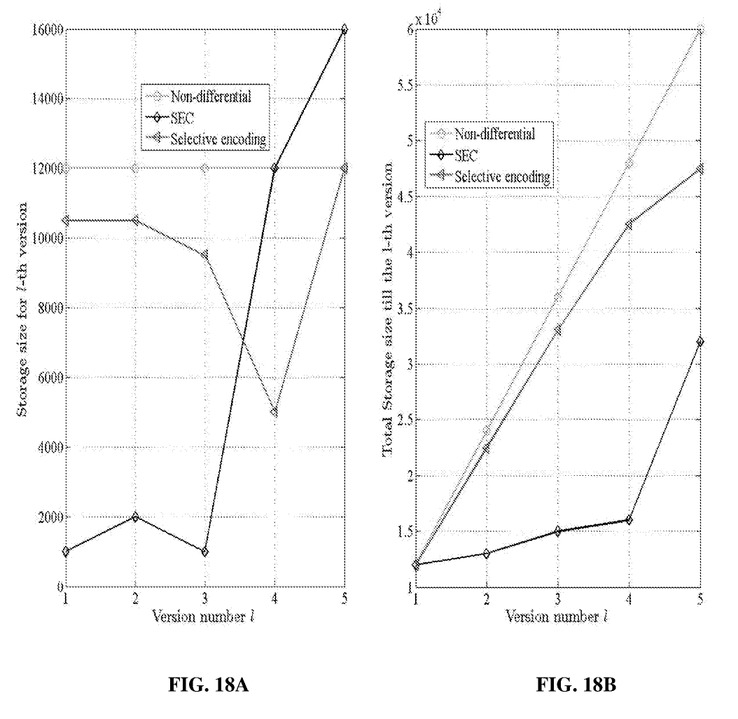

For the different versions of the data object discussed in Examples 7 to 12, the storage size required by the three schemes/techniques, (i) SEC, (ii) selective encoding, and (iii) the non-differential technique are computed and presented in FIGS. 18A and 18B. In particular, FIG. 18A depicts plots illustrating the storage size for the l-th version for 1≦l≦5 and FIG. 18B depicts plots illustrating the cumulative storage size till the l-th version. The ordering of the data objects for the three techniques are {z₂,z₃,z₄,x₄,x₅}, {z₂,z₃,z₄,z₄,x₅} and {x₁,x₂,x₃,x₄,x₅}, respectively. All the three methods start with G=3 for the 1st version (21 chunks for SEC but 20 chunks for the other two). However, for the 5-th version, SEC requires G=4 (equivalent of 32 chunks) while the other two stick to G=3 (equivalent to 24 chunks). Despite this increase in the storage size for the 5^{th} version, the plots in FIG. 18B indicate a significant overall storage savings for the SEC method.

Additional experiments were conducted to store a data object of initial size V=3781 units. The parameters for configuring DiVers are Δ=500, δ=20 and k=8. The selective encoding architecture would also contain k=8 chunks (each of size Δ), however in this case, 219 zero pads appear at the end in the 8-th chunk Appending zero pads at the end is a necessity to employ erasure codes of fixed block length. With that, both methods initially have equal number of zero pads (but at different positions), and hence, the comparison is fair. The average storage savings were computed for the second version when two classes of random insertions are made to the first version, namely: (i) single bursty insertion whose size is uniformly distributed in the interval [1, D], for D=5, 10, 30, 60, and (ii) several single unit insertions uniformly distributed across the object, where the number of insertions is uniformly distributed in the interval [1, P], where P=5, 10, 30, 60. The experiments were repeated 1000 times by generating random insertions and then compute the average storage size for the second version.

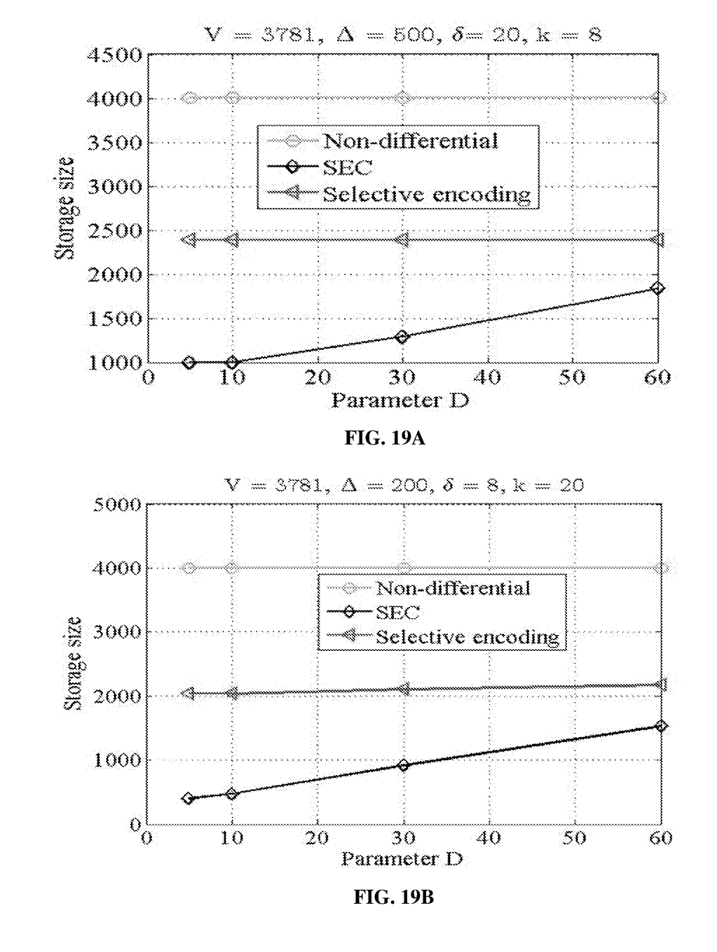

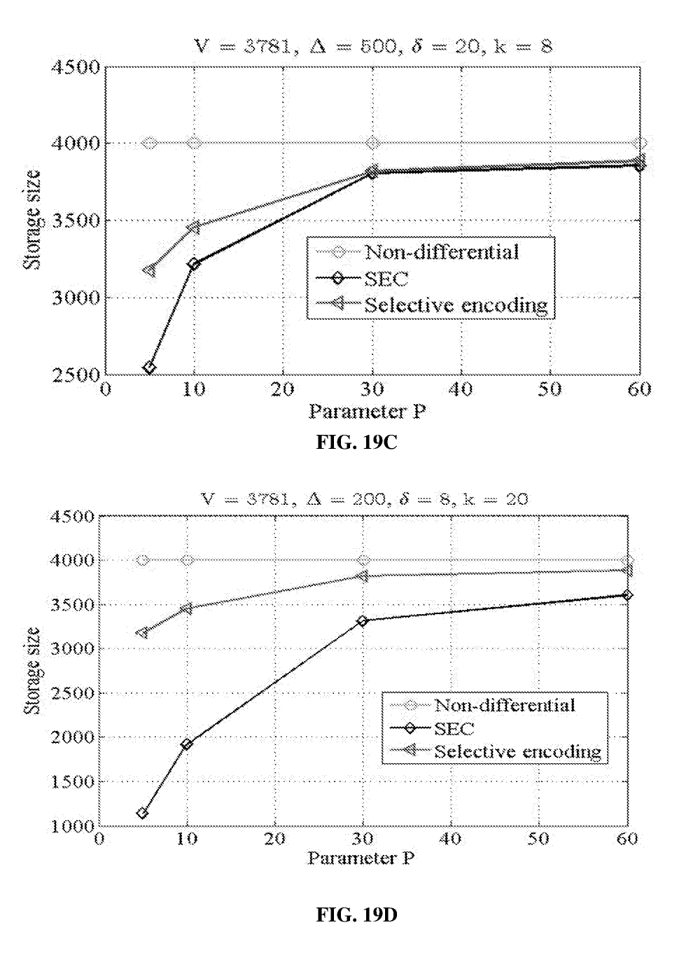

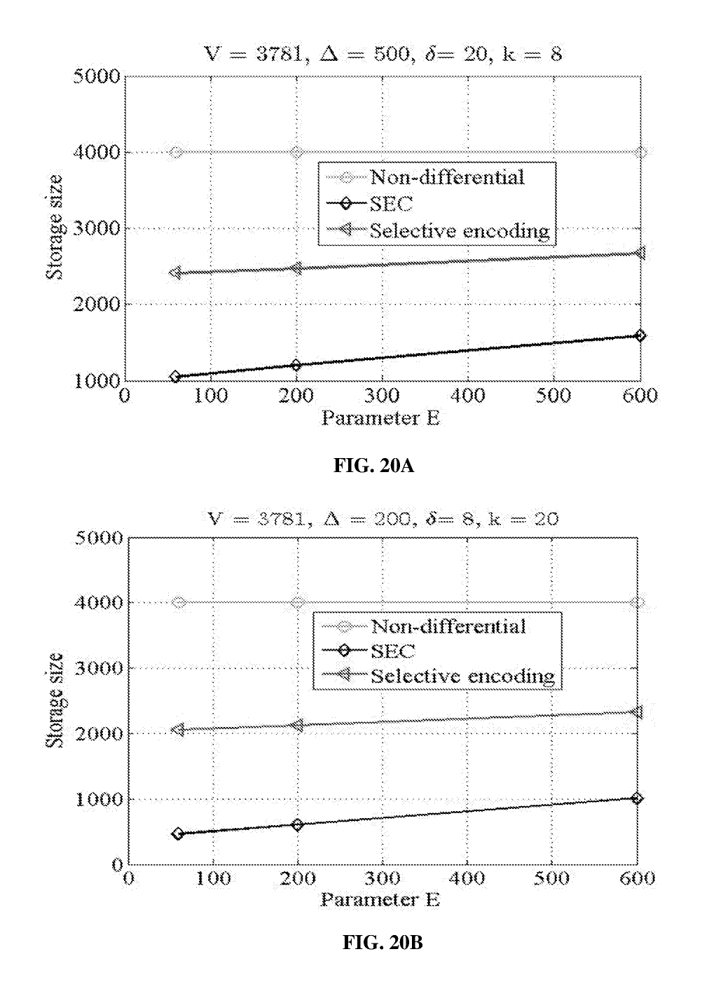

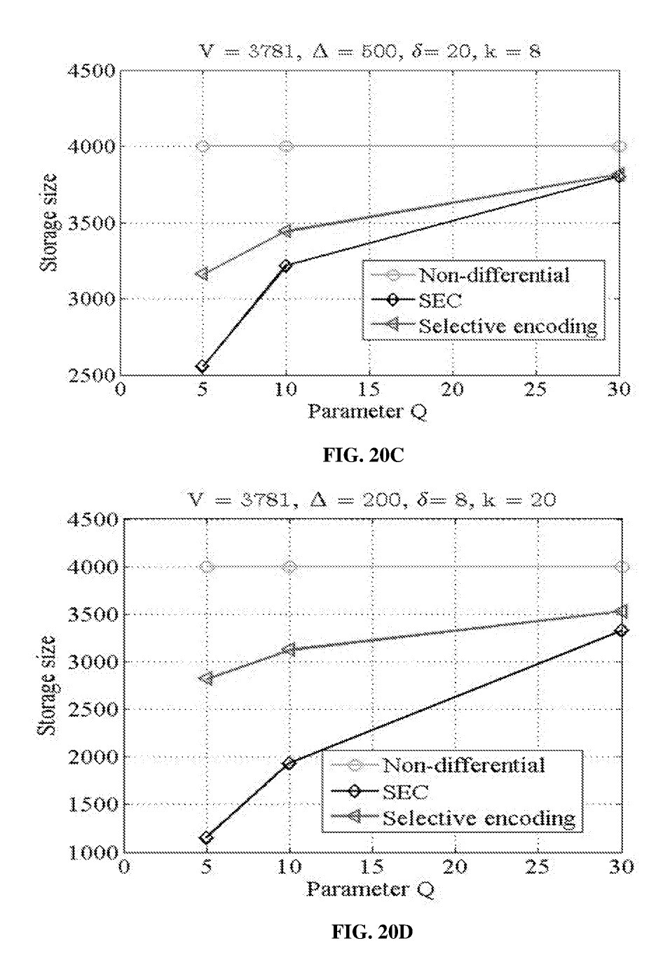

FIGS. 19A to 19D depict plots of the average storage size required for the second version with the three techniques. Similar plots are also presented in FIGS. 19A to 19D with parameters Δ=200, δ=20 and k=20 for the same object. In particular, FIGS. 19A to 19D illustrate DiVers (SEC) against the baseline architecture with respect to insertions, and more specifically, the average storage size for the 2^{nd} version against workloads comprising random insertions. For FIGS. 19A and 19B, the workloads are bursty insertion whose size is uniformly distributed in the interval [1, D], for D ε{5, 10, 30, 60}. For FIGS. 19C and 19D, the workloads are several single unit insertions whose quantity is distributed uniformly in the interval [1, P], for Pε{5, 10, 30, 60}. The plots highlight the superiority of the SEC technique as it can arrest the propagation of changes through intermediate zero pads. Similar experiments were conducted for several classes of random deletions and the results are presented in FIGS. 20A to 20D, which highlights the savings in storage size for the SEC technique. In particular, FIGS. 20A to 20D illustrate DiVers (SEC) against the baseline architecture with respect to deletions, and more specifically, the average storage size for the 2^{nd} version against workloads comprising random deletions. For FIGS. 20A and 20B, the workloads are bursty deletions whose size is uniformly distributed in the interval [1, E], for Eε{60, 200, 600}. For FIGS. 20C and 20D, the workloads are several single unit insertions whose quantity is distributed uniformly in the interval [1, Q], for Qε{5, 10, 30}.

Allocation of Chunks within a Batch

The placement strategy will now be described for the kG chunks (after appending N zero-chunks) within one batch. The set {C₁, C₂, . . . , C_{kG}} can be allocated in two of the following ways:

Allocation 1:

to distribute the chunks of each group across the k chunk servers so that the t-th server holds the chunks {Cₜ, Cₜ₊ₖ, . . . , C_{t+(G-1)k}} for t=1, 2, . . . , k, or

Allocation 2:

to distribute the set of G consecutive chunks on each server, i.e., the t-th server holds the chunks {C_{(t-1)c+1}, C_{(t-1)G+2}, . . . , C_{(t-1)G+G}} for t=1, 2, . . . , k.

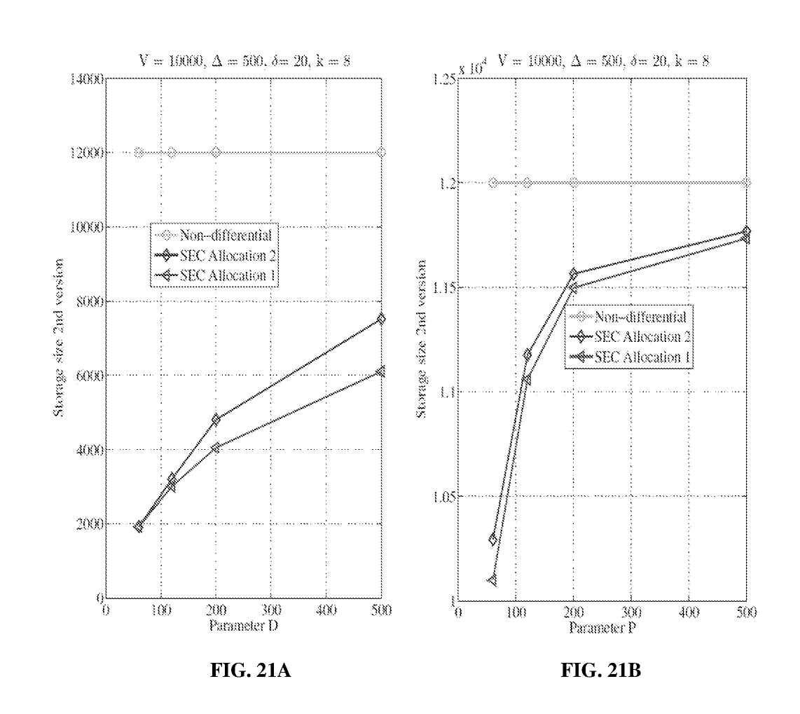

Comparison of the two allocations is important to reduce the communication overhead while updating the file contents. For the Allocation 2, the overflow between the G consecutive chunks can be shared within the server, and as a result, this allocation would require the servers to establish connection at most k−1 times. However, for Allocation 1, the communication overhead is higher as consecutive chunks are placed on different servers, thus requiring communication at most kG−1 times. For the parameters Δ=500, δ=20 and k=8 discussed in Example 7, experiments were conducted to determine the average storage savings for the second version against the insertion models discussed hereinbefore under Comparison with the Baseline Architecture, but with parameters D, Pε{60, 120, 200, 600}. For this experiment, we have G=3, because of which the 1st server, for instance, stores {C₁, C₉, C₁₇} and {C₁, C₂, C₃} for Allocation 1 and Allocation 2, respectively. The results are presented in FIGS. 21A and 21B which shows that Allocation 2 does not provide storage gains with respect to Allocation 1, although their communication overheads stand reversed in comparison. In particular, FIGS. 21A and 21B compare allocation strategies for DiVers (SEC) against random insertions. For FIG. 21A, the workload is bursty insertions distributed over [1, D] for Dε{60, 120, 200, 500}. FIG. 21B illustrate plots against several single unit insertions distributed over [1, P] for Pε{60, 120, 200,500}. Thus, the right choice of the allocation depends on the available system resources to handle the storage and networking overhead. For instance, experiment results for several single insertion workloads suggest the use of Allocation 2, since the loss in storage savings is marginal compared to the gains in communication overhead.

### On the Choice of Chunk Size Δ

The possibility of determining the right chunk size Δ was examined given the knowledge of the insertion distribution. In the experiments conducted, different versions of a data object of initial size V=10000 units with k=8 were stored so as to find the best pair (Δ, δ) among (500, 20), (250, 10) and (125, 5). The workloads comprise of single bursty insertions and several single unit insertions with parameters D, Pε{5, 10, 30, 60}. The different options for (Δ, δ) (in the order of decreasing size of Δ) distribute the zero pads across the file structure at more places, but of smaller patches. Note that the ratio

$$\frac{δ}{Δ}$$

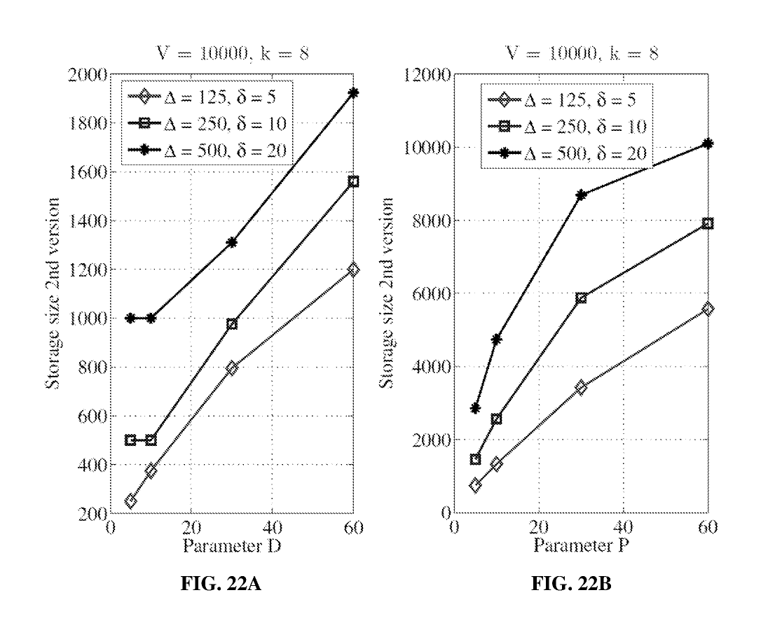

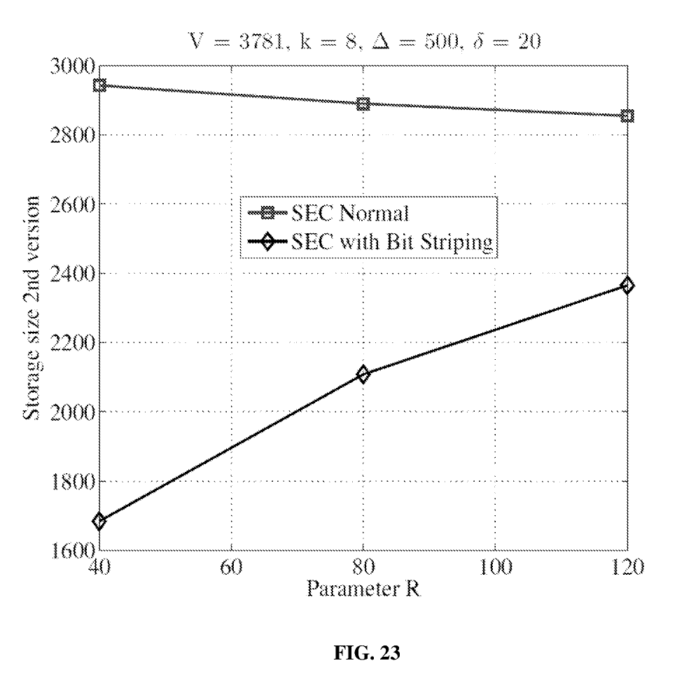

is held constant for a fair comparison. Intuitively, with smaller chunk size the strategy must absorb smaller size insertions within the chunk, thereby contributing to reduced storage size compared to larger Δ. For Δ=500, 250, 125, G=3, 6, 11 respectively. The storage savings for different pairs (Δ, δ) are presented in FIGS. 22A and 22B which show the benefit of breaking the object into smaller chunks especially given that the insertions are of smaller sizes. In particular, FIGS. 22A and 22B compare different choices of (Δ, δ) for V=10000 and k=8, and illustrate the average storage size for the 2^{nd} version against workloads comprising random insertions. For FIG. 22A, workloads are bursty insertions whose size is uniformly distributed in the interval [1, D] for Dε{5, 10, 30, 60}. For FIG. 22B, workloads are several single unit insertions whose quantity is distributed uniformly in the interval [1, P] for Pε{5, 10, 30, 60}. Thus, if the maximum insertion size or distribution of insertions in general is known, it is possible to optimize on the pair (Δ, δ) to gain maximum savings in storage. On the flip side, smaller Δ increases the number of groups G which in turn increases the number of encoding blocks for erasure coding. Since the blocks are of smaller size, the actual computation overheads for coding do not increase, however, more importantly, the size of the meta-information increases. Also, from the discussion hereinbefore under On the Choice of Chunk Size Δ, larger G would also increase the worst-case communication overhead for exchanging the updates with Allocation 1.
Chunks with Bit Striping Strategy

A preferred strategy according to various embodiments of the present invention is now analysed to synthesize chunks for workloads that involve several single insertions with sufficient spacing. For better understanding, an example will first be discussed. Consider storing a data object of size V=3871 units using the DiVers parameters Δ=500, δ=20, k=8. Assume that 3 units of insertions are made to the object at the positions 1, 481 and 961, which translates to modifications of the chunks C₁, C₂ and C₃, respectively. Thus, due to just 3 single unit insertions, three chunks are modified because of which the difference object after compression will be of size 3000 units. Instead, imagine striping every chunk into k partitions at the bit level such that the δ zero pads are equally distributed across the partitions. Then, create a new set of k chunks as follows: create the t-th chunk for 1≦t≦k by concatenating the contents in the t-th partition of all the original chunks. Applying this striping to the example, only one chunk (after striping) will be modified, hence, this strategy would need only 1000 units for storage after compression.

For the above example, the insertions are spaced exactly at intra-distance Δ−δ units to highlight the benefits, although in practice, the insertions can as well be approximately around that distance to reap the benefits. Experiments were conducted by introducing 3 random insertions into the file where the first position is chosen at random while the second and the third are chosen with intra-distance (with respect to the previous insertion) that is uniformly distributed in the interval [Δ−δ−R, Δ−δ+R] when Rε{40, 80, 120}. For this experiment, the average storage size for the second version is shown in FIG. 23. In particular, FIG. 23 depicts plots illustrating comparison of SEC methods with and without bit striping. The average storage size for the second version against workload that has 3 single unit insertions with intra-distance uniformly distributed in the interval [Δ−δ−R, Δ−δ+R] for Rε{40, 80, 120}, Δ=500 and δ=20. FIG. 23 can be observed to show a significant reduction in storage size for the striping method when compared to the conventional method. It can be observed that as R increases, there is higher chance for the neighbouring insertions to not fall in the same partition number of different chunks, thus diminishing the gains.

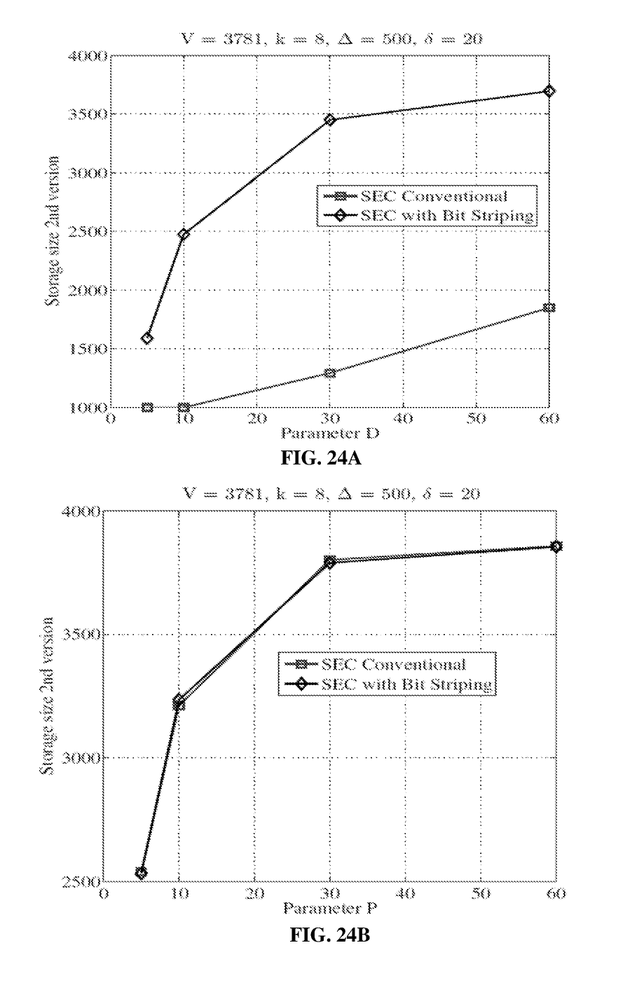

The striping method was also tested against two types of workloads, namely, the bursty insertion (with parameter Dε{5, 10, 30, 60}) and the randomly distributed single insertions with parameter Pε{5, 10, 30, 60}. For the workloads with single insertions, the spacing between the insertions is uniformly distributed and not necessarily at intra-distance Δ−δ. In FIGS. 24A and 24B, the average storage size for the second version against such workloads is illustrated. In particular, FIG. 24A illustrate plots comparing SEC methods with and without bit striping against bursty insertions with parameters D ε{5, 10, 30, 60} and FIG. 24B illustrate plots comparing SEC methods with and without bit striping against randomly distributed single insertions with parameters Pε{5, 10, 30, 60}. The plots show significant loss for the striping method against the former workload (as they are not designed for such patterns), whereas the storage savings are approximately close to the conventional method against the latter workload. Therefore, according to various example embodiments of the present invention, if the insertion pattern is known to be distributed a priori, then the striping method is preferably selected as it provides similar performance as that of the conventional method with a potential to provide reduced storage savings for some special distributed insertions.

Accordingly, an erasure coding based distributed storage (DiVers) system architecture for versioned data has been disclosed according to various example embodiments of the present invention. In the example embodiments, the design of DiVers is guided by the characteristics of the Differential Erasure Coding (DEC) (also referred to as Sparsity Exploiting Codes (SEC)) described hereinbefore according to various embodiments of the present invention, particularly, in its exploitation of sparsity in version deltas (difference object). In the experiments conducted, DiVers achieved between 20-70% reduction in overall storage costs and I/O overhead for a diverse set of workloads simulated. While the performance gains witnessed in DiVers is brought about from its strong coupling with SEC, it will be appreciated by a person skilled in the many of its design aspects (changing size of mutable content, keeping track of erasure coded fragments of different versions, etc.) are of wider relevance, and is applicable in accommodating versioned data in erasure coded storage systems.

### Data Structures for Meta-Information Encapsulation in Divers

Example data structures for meta-information encapsulation in DiVers will now be described according to various example embodiments of the present invention. Similar to the baseline architecture, metadata in DiVers may comprise of the list of file names, mapping from file names to chunk indices, and then the mapping from chunk indices to chunk servers along with their physical address. In this example, new inclusions needed may be enumerated to the list to facilitate the archival (and retrieval) of versioned data. The metadata can be classified into two types, namely, (i) the static contents, which are independent of the files, therefore, not mutable, and (ii) the dynamic contents, that are updated based on different versions of the file. The master server allots some storage space for the metadata of each version, which in turn has pointers to the metadata of the preceding, succeeding and the latest version of the batch. Such a data structure (akin to classical linked list) assists the master to traverse through the details of different versions, for the object retrieval. The static and dynamic parameters which may be necessary in DiVers according to various example embodiments are tabulated in Table V and Table VI below, respectively.

TABLE V
STATIC PARAMETERS (META-INFORMATION) FOR DIVERS

| Variable Name | Description |
|---|---|
| CHUNK SIZE | Size of a chunk (Δ units) |
| ZP INIT | Initial zero pads per chunk (δ) |
| CODING BLOCKS | Number of blocks for erasure coding (k) |
| ER CODE | An (n, k) erasure code |
| COMP MAT | $\{ {Φ}_{γ} \vert γ = 1 , 2 , … , \frac{k}{2} - 1 \}$ |

TABLE VI
DYNAMIC PARAMETERS (META-INFORMATION) FOR DIVERS

| Variable Name | Description |
|---|---|
| FILE ID | An identification for the file |
| VER NUM | Version number |
| BATCH NUM | Batch number |
| FILE SIZE | Size of the file |
| NUM CHUNK | Number of chunks (M) |
| NUM GROUP | Group size (G) |
| ZP END | Number of zero pads in the Mth chunk |
| NUM ZC | Number of zero-chunks N |
| NUM ZP CHUNK | Number of zero-chunks in each chunk |
| TOT ZP | Total number of zero pads within the group |
| ENC FLAG | Flag determining encoding method |
| CLUST ID | Cluster ID that stores this version |
| MAP CI CS | Mapping from chunk indices to the chunk servers |
| HDS ADDRESS | The address of the helpdesk server |
| CS ADDRESS | The physical address of the chunk servers |
| SPARSITY | Sparsity γ in each group |
| COMP OBJ SIZE | Size of the compressed object |
| SYMB SIZE | $Symbol size \frac{2 l Δ}{k} of the erasure code$ |
| PREC VER | Pointer to preceding version |
| NEXT VER | Pointer to next version |
| LATEST VER | Pointer to latest version of the batch |

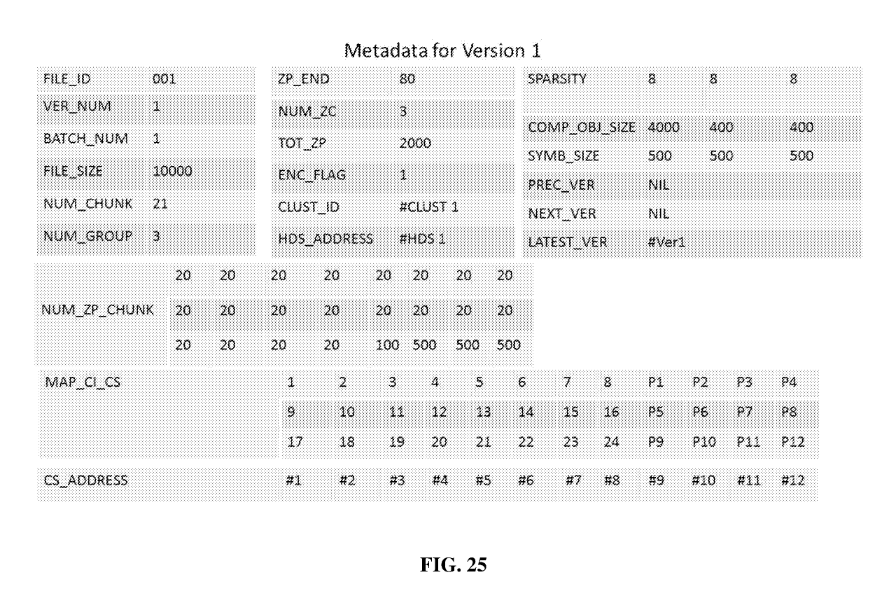

FIGS. 25 to 27 present snapshots of the metadata for the first 2 versions of the file discussed in Examples 7 to 12. In particular, FIG. 8 captures the contents of the data structure when the first version of the object (objected encoded at this stage is x₁) in Example 7 is saved into DiVers. This file is first given an identification number through FILE ID=001 before filling the rest of the parameters with respect to DiVers. The parameters of interest are preferably either scalars, vectors, or even two-dimensional quantities depending on their utility. For instance, the variables NUM ZP CHUNK (9th variable in Table VI) and MAP CI CS (13th variable) are both two dimensional, as they maintain the allocation of zero pads and the chunk indices, respectively, across chunk servers and groups, i.e., columns and rows against the variables correspond to chunk servers and groups, respectively. On the other hand, variables such as COMP OBJ SIZE (17th variable) and SYMB SIZE (18^{th} variable) are one-dimensional as they keep track of the contents that change across groups. The flag ENC FLAG is set to 1 which indicates that the object is encoded in full. Since the snapshot is taken at the end of the first version, the label LATEST VER is pointing to itself as the latest version of the batch. Finally, this file being the only version so far, makes the variables PREC VER and NEXT VER store NIL. Apart from the above variables, the rest of the contents in FIG. 25 display other necessary information for the archival of data. In the process of archiving different versions of the object, new instantiations of the data structure are created when subsequent versions are saved into DiVers. Concurrently, existing data structures for the previous versions are also updated.

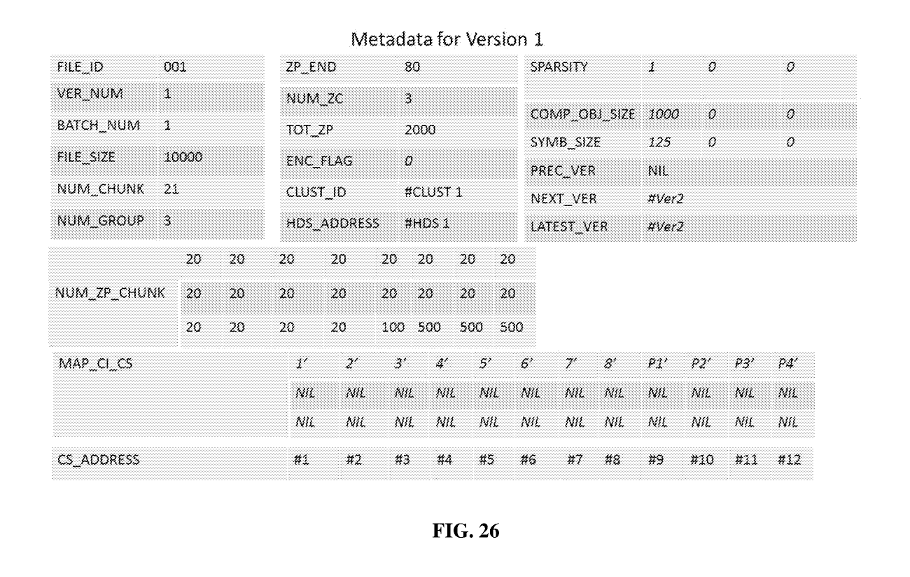

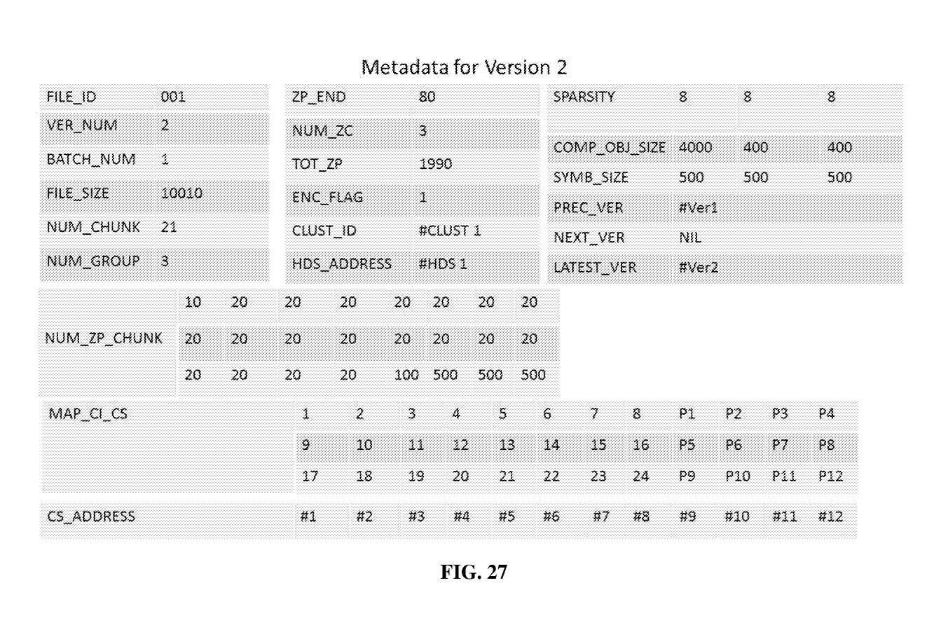

The changes in metadata when the second version of the object (as in Example 9) is created will now be described. In FIGS. 26 and 27, the snapshots of the metadata for the first two versions are shown. In particular, FIG. 26 depicts a snapshot of the metadata for the first version capturing the changes in its contents when the second version is saved. In comparison with the metadata in FIG. 25, the changes are shown italicised. The object encoded at this stage is the difference object z₂. FIG. 27 depicts a snapshot of the new instantiation of the data structure for the second version discussed in Example 9. The encoded object is the complete latest version, i.e., x₂. Therefore, as shown in FIG. 26, the existing data structure for the first version is updated (changes shown in italics), while a new instantiation is created for the second version and shown in FIG. 27. Based on the reverse differential strategy, the second version is encoded in full whereas the first version is encoded differentially. Thus, the variable ENC FLAG gets toggled from 1 to 0 in the metadata for the first version. At the same time, other details pertaining to SPARSITY, COMP OBJ SIZE and SYMB SIZE are also modified. It can be observed that the newly created structure for the second version is updated with the information regarding the object size and the remaining number of zero pads.

### Cluster Management and Protocols

An example protocol to guide coordination between the chunk servers and the master to employ SEC and store the difference objects will now be described according to various example embodiments of the present invention. The metadata definitions described hereinbefore with respect to the DEC/SEC are utilized to layout an example deterministic protocol to describe the archival and retrieval of different versions.

### Resources

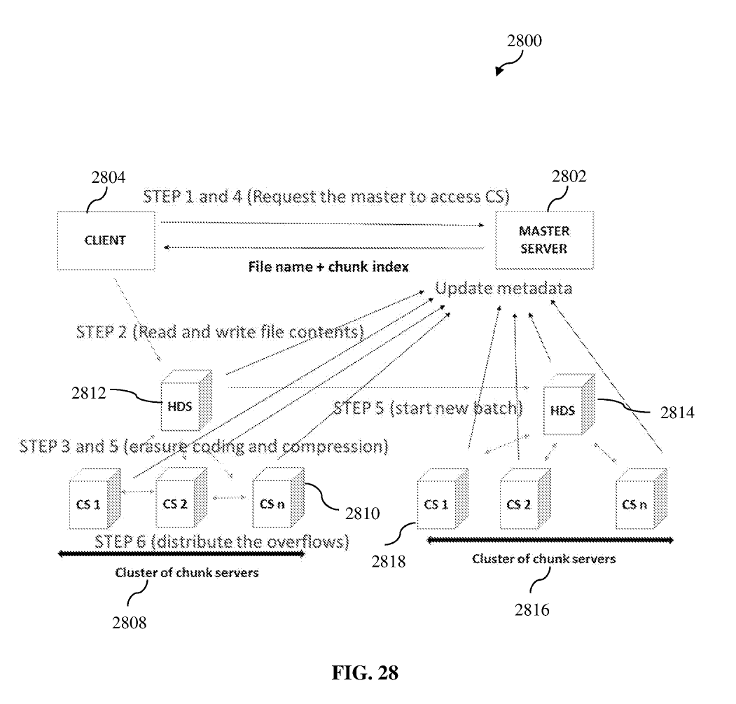

FIG. 28 depicts a schematic diagram of a distributed storage system 2800 (DiVers architecture) according to various example embodiments of the present invention. The system 2800 may comprise a master server 2802 that stores the metadata and controls the information flow by interacting with the client 2804 and the chunk servers 2806, and several clusters 2808 of chunk servers 2810 (each cluster 2810 containing at least n servers) that stores the file contents. Each cluster 2808 may have an associated helpdesk server (HDS) 2812 (or secondary server), that coordinates with the master server 2802 and performs certain centralized tasks such as compression and erasure coding. In practice, the clusters 2808 may be dynamically determined, and the HDS 2812 may be allocated per data object based on the lease model similar to GFS, but for simplicity and clarity, these are kept static in the example.

### Protocol

Example interactions between the client 2804 and the DiVers system elements will now be described according to an example embodiment.

Step 1:

A client 2804 requests access to a master server 2802 to write the 1st version. In response, the master server 2802 allocates a HDS 2812 (in some cluster) and passes the necessary permissions.

Step 2:

The client 2804 creates a file of size V units in the master server 2802. The file is divided into G groups each containing k chunks.

Step 3:

First, the kG chunks are distributed across k chunk servers within a cluster 2808, e.g., as per Allocation 1 described hereinbefore. Then the HDS 2812 computes the parity chunks and allocates them to n−k new chunk servers 2810 in the same cluster 2808. The metadata in the master server 2802 encapsulates all the relevant details discussed above under Data Structures for Meta-Information Encapsulation in DiVers.

Step 4:

The client 2804 requests the master server 2802 to create the (j+1)-th version, for j>1. The master provides the address of the HDS 2812 to the client 2804. Upon contacted by the client 2804, the HDS 2812 reads all the systematic chunks (from k chunk servers 2810) and passes them to the client 2804. It will be appreciated that decoding using non-systematic chunks may be needed in case of chunk server failures.

Step 5:

The client 2804 edits these chunks and saves them back, after which the chunks are returned to the systematic chunk servers 2810. Each chunk server 2810 reports the changes in its chunk size to the HDS 2812, based on which the HDS 2812 takes a decision whether to reset the differential encoding cycle. If agreed to RESET, the HDS 2812 passes the systematic chunks to a new HDS 2814 in another cluster 2816, which in turn repeats STEP 3 on the chunk servers 2818 in its cluster 2816. ELSE, go to STEP 6.

Step 6:

The k chunk servers 2810 cache their previous version locally. Then, they share their overflows among them, until all the chunks are updated. After the propagation of updates, details regarding the remaining number of zero pads are updated in the metadata. Then, the new set of chunks are forwarded to the HDS 2812, where second part of STEP 3 is repeated.

Step 7:

After STEP 6, each chunk server 2810 locally computes the difference between the chunks (that it hosts) of two successive versions. Then each chunk server 2810 forwards its G difference chunks to the HDS 2812 which compresses the difference object within each group, and redistributes the blocks of size 2γΔ/k units back to the k chunk servers 2810. After this, these k chunk servers 2810 store the blocks in some chunks and forward the details of the chunk indices and the size of the blocks to the master server 2802. Finally, the HDS 2812 follows STEP 3 but this time they pass the smaller sized blocks.

While embodiments of the present invention have been particularly shown and described with reference to specific embodiments, it should be understood by those skilled in the art that various changes in form and detail may be made therein without departing from the scope of the present invention as defined by the appended claims. The scope of the present invention is thus indicated by the appended claims and all changes which come within the meaning and range of equivalency of the claims are therefore intended to be embraced.

1. A method of encoding multiple versions of data, the method comprising:
computing a difference between a version of a data object and a subsequent version of the data object to produce a difference object;
determining a sparsity level of the difference object;
determining whether the sparsity level satisfies a predetermined condition; and
compressing the difference object to produce a compressed difference object and erasure encoding the compressed difference object to produce a codeword if the sparsity level is determined to satisfy the predetermined condition.

2. The method according to claim 1, wherein compressing the difference object comprises applying compressed sensing to the difference object to produce the compressed difference object.

3. The method according to claim 2, wherein applying compressed sensing to the difference object comprises applying a measurement matrix to the difference object to produce the compressed difference object, wherein the measurement matrix satisfies a condition that every of a number of columns of the measurement matrix are linearly independent, the number being two times the sparsity level of the difference object.

4. The method according to claim 1, wherein the difference object comprises a matrix representing the difference between said version of the data object and said subsequent version of the data object.

5. The method according to claim 1, wherein the predetermined condition relates to a sparsity level threshold.

6. The method according to claim 1, wherein erasure encoding the compressed difference object comprises applying an erasure code to the compressed difference object, the erasure code being selected from a set of erasure codes based on the sparsity level of the difference object determined, the set of erasure codes comprising a plurality of erasure codes for a plurality of sparsity levels, respectively.

7. The method according to claim 6, wherein the data object is divided into a plurality of data blocks and the predetermined condition is whether the sparsity level of the difference object is less than half of the number of the plurality of data chunks.

8. The method according to claim 1, wherein one erasure code is provided for all sparsity levels that satisfy the predetermined condition, and erasure encoding the compressed difference object comprises applying said one erasure code to the compressed difference object.

9. The method according to claim 8, wherein the predetermined condition is whether the sparsity level of the difference object is less than or equal to a predetermined threshold level.

10. The method according to claim 8, wherein compressing the difference object comprises applying a Cauchy Matrix to the difference object to produce the compressed difference object.

11. The method according to claim 1, wherein a plurality of erasure codes is provided for a plurality of sparsity levels, and erasure encoding the compressed difference object comprises applying one of the plurality of erasure codes to the compressed difference object.

12. The method according to claim 1, further comprising erasure encoding the difference object to produce a codeword if the sparsity level of the difference object is determined to not satisfy the predetermined condition.

13. The method according to claim 1, further comprising erasure encoding said subsequent version of the data object to produce a codeword if the sparsity level of the difference object is determined to not satisfy the predetermined condition.

14. The method according to claim 1, wherein the codeword produced is for said subsequent version of the data object.

15. The method according to claim 1, wherein the codeword produced is for said version of the data object.

16. The method according to claim 15, further comprising erasure encoding said subsequent version of the data object to produce a codeword for said subsequent version of the data object.

17. The method according to claim 1, further comprising distributing components of the codeword produced to a plurality of storage nodes for storage.

18. The method according to claim 1, further comprising zero padding the data object with a plurality of zero pads such that the data object comprises file contents and the plurality of zero pads.

19. The method according to claim 18, wherein the number of zero pads in said subsequent version of the data object increases or decreases with respect to the number of zero pads in said version of the data object based on a change in the size of the file contents in said subsequent version of the data object with respect to the size of the file contents in said version of the data object.

20. The method according to claim 19, wherein:
the number of zero pads in said subsequent version of the data object decreases with respect to the number of zero pads in said version of the data object when the change results in an increase in the size of the file contents in the subsequent version of the data object with respect to the size of the file contents in said version of the data object, and
the number of zero pads in said subsequent version of the data object increases with respect to the number of zero pads in said version of the data object when the change results in a decrease in the size of the file contents in said subsequent version of the data object with respect to the size of the file contents in said version of the data object.

21. A method of decoding encoded multiple versions of data, the encoded multiple versions of data comprising a plurality of codewords, each codeword corresponding a respective version of a data object, the method comprising:
erasure decoding a codeword corresponding to a version of the data object from the plurality of codewords to obtain a compressed difference object, the difference object representing a difference between said version of the data object and another version of the data object;
decompressing the compressed difference object to recover the difference object; and
recovering said version of the data object based on at least the recovered difference object and said another version of the data object.

22. An encoder system for encoding multiple versions of data, the encoder comprising:
a difference object generator module configured to compute a difference between a version of a data object and a subsequent version of the data object to produce a difference object;
a sparsity level determination module configured to determine a sparsity level of the difference object;
a sparsity level comparator module configured to determine whether the sparsity level satisfies a predetermined condition;
a compression module configured to compress the difference object to produce a compressed difference object; and
an erasure encoder configured to encode the compressed difference object to produce a codeword,
wherein the compression module is configured to compress the difference object and the erasure encoder is configured to encode the compressed difference object if the sparsity level is determined by the sparsity level comparator module to satisfy the predetermined condition.

23. The encoder system according to claim 22, wherein the predetermined condition relates to a sparsity level threshold.

24. A distributed storage system, the system comprising:
a plurality of secondary servers, each secondary server configured to store codewords for multiple versions of a data object; and
a group server associated with the plurality of secondary servers, wherein
each secondary server comprises a difference object generator module configured to compute a difference between a version of the data object and a subsequent version of the data object to produce a difference object, and
the group server comprises:
a sparsity level determination module configured to determine a sparsity level of the difference object received from the secondary server;
a sparsity level comparator module configured to determine whether the sparsity level satisfies a predetermined condition;
a compression module configured to compress the difference object to produce a compressed difference object; and
an erasure encoder configured to encode the compressed difference object to produce a codeword for storing in the secondary server,
wherein the compression module is configured to compress the difference object and the erasure encoder is configured to encode the compressed difference object if the sparsity level is determined by the sparsity level comparator module to satisfy the predetermined condition.

25. The distributed storage system according to claim 24, further comprising a master server configured for facilitating communication between a client and a plurality of the group servers for storing multiple versions of data in the plurality of secondary servers.

26. The distributed storage system according to claim 24, wherein the predetermined condition relates to a sparsity level threshold.

27. A method of storing multiple versions of data in a distributed storage system, the distributed storage system comprising:
a plurality of secondary servers, each secondary server configured to store codewords for multiple versions of a data object; and
a group server associated with the plurality of secondary servers,
the method comprising:
computing, at one of the plurality of secondary servers, a difference between a version of a data object and a subsequent version of the data object to produce a difference object;
determining, at the group server, a sparsity level of the difference object received from the secondary server;
determining, at the group server, whether the sparsity level satisfies a predetermined condition; and
compressing, at the group server, the difference object to produce a compressed difference object and erasure encoding, at the group server, the compressed difference object to produce a codeword for storage in the secondary server if the sparsity level is determined to satisfy the predetermined condition.

28. The distributed storage system according to claim 27, wherein the predetermined condition relates to a sparsity level threshold.

29. A computer program product, embodied in one or more non-transitory computer-readable storage mediums, comprising instructions executable by one or more computer processors to perform a method of encoding multiple versions of data, the method comprising:
computing a difference between a version of a data object and a subsequent version of the data object to produce a difference object;
determining a sparsity level of the difference object;
determining whether the sparsity level satisfies a predetermined condition; and
compressing the difference object to produce a compressed difference object and erasure encoding the compressed difference object to produce a codeword if the sparsity level is determined to satisfy the predetermined condition.
